(19) United States
(12) Patent Application Publication
(10) Pub. No.: US 2011/0104868 A1
(43) Pub. Date: May 5, 2011

(54) METHOD OF FORMING SEMICONDUCTOR DEVICE

(75) Inventors: Shingo UJIHARA, Tokyo (JP); Kazuma SHIMAMOTO, Tokyo (JP)

(73) Assignee: ELPIDA MEMORY, INC., Tokyo (JP)

(21) Appl. No.: 12/912,023

(22) Filed: Oct. 26, 2010

(30) Foreign Application Priority Data
Oct. 29, 2009 (JP) 2009-248913

(51) Int. Cl. H01L 21/31

(52) U.S. Cl. 438/425; 257/E21.24

(57) ABSTRACT

A method of forming a semiconductor device include the following processes. A groove is formed in a semiconductor substrate. A first insulating film is formed on a bottom surface of the groove and a second insulating film on a side surface of the groove. The second insulating film is thinner than the first insulating film. A conductive layer is formed on the first insulating film.

### BACKGROUND OF THE INVENTION

1. Field of the Invention

The present invention relates to a method of forming a semiconductor device.

Priority is claimed on Japanese Patent Application No. 2009-248913, filed Oct. 29, 2009, the content of which is incorporated herein by reference.

2. Description of the Related Art

As miniaturization of semiconductor devices has progressed in recent years, the planar regions occupied by semiconductor elements have decreased in size. For example, the size of the region (active region) in which a transistor is formed has gradually decreased. As the size of this active region decreases, there occurs a problem such as the short channel effect due to a decrease in the channel length and the channel width of a planar-type transistor.

Consequently, since the channel length and the channel width are increased even in the miniaturized region, a vertical-type transistor has been proposed in place of the planar-type transistor.

A buried bit line is connected to a source or drain region of this vertical-type transistor. This buried bit line is formed as follows.
(1) A trench is formed by etching a semiconductor substrate.
(2) After the inner wall of the trench is thermally-oxidized, the bit line is formed within the trench by a CVD method.

Japanese Unexamined Patent Application Publication No. 2009-10366 discloses a semiconductor device in which the buried bit line is connected to a diffusion layer of the vertical-type transistor, and the bit line includes a silicon material region contacting the diffusion layer and a low-resistance region made of materials having lower electrical resistance than that of this silicon material region.

### SUMMARY

In one embodiment, a method of forming a semiconductor device may include, but is not limited to, the following processes. A groove is formed in a semiconductor substrate. A first insulating film is formed on a bottom surface of the groove and a second insulating film on a side surface of the groove. The second insulating film is thinner than the first insulating film. A conductive layer is formed on the first insulating film.

In another embodiment, a method of forming a semiconductor device may include, but is not limited to, the following processes. A groove is formed in a silicon substrate. A first insulating film is formed on a bottom surface of the groove and a second insulating film on a side surface of the groove. At least the second insulating film is formed by thermal oxidation. The second insulating film is thinner than the first insulating film. The first insulating film and the second insulating film are selectively removed to expose a selected region of the side surface of the groove. A contact layer is formed on the selected region of the side surface of the groove. An impurity is thermally diffused from the contact layer into the semiconductor substrate through the selected region of the side surface of the groove to form a diffusion layer in the semiconductor substrate. The diffusion layer is adjacent to the selected region of the side surface of the groove. The diffusion layer contacts the contact layer. A conductive layer is formed on the first insulating film.

In still another embodiment, a method of forming a semiconductor device may include, but is not limited to, the following processes. A trench groove is formed in a silicon substrate. A bottom surface of the groove is thermally oxidized to form a first insulating film on the bottom surface of the groove. A side surface of the groove is thermally oxidized to form the second insulating film on the side surface of the groove. The second insulating film is thinner than the first insulating film. A bit line is formed on the first insulating film.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary schematic perspective view illustrating a semiconductor device in accordance with a first preferred embodiment of the present invention;

FIG. 2 is a fragmentary plan view illustrating a layout of silicon pillars in the semiconductor device of FIG. 1;

FIG. 3 is a fragmentary plan view illustrating a semiconductor substrate in a step involved in a method of forming a semiconductor device of FIGS. 1 and 2;

FIG. 4 is a fragmentary cross sectional elevation view illustrating the semiconductor substrate, taken along an A-A line of FIG. 3;

FIG. 5 is a fragmentary cross sectional elevation view illustrating the semiconductor substrate in a step, subsequent to the step of FIGS. 3 and 4, involved in the method of forming the semiconductor device of FIGS. 1 and 2;

FIG. 6 is a fragmentary cross sectional elevation view illustrating the semiconductor substrate in a step, subsequent to the step of FIG. 5, involved in the method of forming the semiconductor device of FIGS. 1 and 2;

FIG. 7 is a fragmentary cross sectional elevation view illustrating the semiconductor substrate in a step, subsequent to the step of FIG. 6, involved in the method of forming the semiconductor device of FIGS. 1 and 2;

FIG. 8 is a fragmentary cross sectional elevation view illustrating the semiconductor substrate in a step, subsequent to the step of FIG. 7, involved in the method of forming the semiconductor device of FIGS. 1 and 2;

FIG. 9 is a fragmentary cross sectional elevation view illustrating the semiconductor substrate in a step, subsequent to the step of FIG. 8, involved in the method of forming the semiconductor device of FIGS. 1 and 2;

FIG. 10 is a fragmentary cross sectional elevation view illustrating the semiconductor substrate in a step, subsequent to the step of FIG. 9, involved in the method of forming the semiconductor device of FIGS. 1 and 2;

FIG. 11 is a fragmentary cross sectional elevation view illustrating the semiconductor substrate in a step, subsequent to the step of FIG. 10, involved in the method of forming the semiconductor device of FIGS. 1 and 2;

FIG. 12 is a fragmentary cross sectional elevation view illustrating the semiconductor substrate in a step, subsequent to the step of FIG. 11, involved in the method of forming the semiconductor device of FIGS. 1 and 2;

FIG. 13 is a fragmentary cross sectional elevation view illustrating the semiconductor substrate in a step, subsequent to the step of FIG. 12, involved in the method of forming the semiconductor device of FIGS. 1 and 2;

FIG. 14 is a fragmentary cross sectional elevation view illustrating the semiconductor substrate in a step, subsequent to the step of FIG. 13, involved in the method of forming the semiconductor device of FIGS. 1 and 2;

FIG. 15 is a fragmentary cross sectional elevation view illustrating the semiconductor substrate in a step, subsequent to the step of FIG. 14, involved in the method of forming the semiconductor device of FIGS. 1 and 2;

FIG. 16 is a fragmentary cross sectional elevation view illustrating the semiconductor substrate in a step, subsequent to the step of FIG. 15, involved in the method of forming the semiconductor device of FIGS. 1 and 2;

FIG. 17 is a fragmentary cross sectional elevation view illustrating the semiconductor substrate in a step, subsequent to the step of FIG. 16, involved in the method of forming the semiconductor device of FIGS. 1 and 2;

FIG. 18 is a fragmentary cross sectional elevation view illustrating the semiconductor substrate in a step, subsequent to the step of FIG. 17, involved in the method of forming the semiconductor device of FIGS. 1 and 2;

FIG. 19 is a fragmentary cross sectional elevation view illustrating the semiconductor substrate in a step, subsequent to the step of FIG. 18, involved in the method of forming the semiconductor device of FIGS. 1 and 2;

FIG. 20 is a fragmentary cross sectional elevation view illustrating the semiconductor substrate in a step, subsequent to the step of FIG. 19, involved in the method of forming the semiconductor device of FIGS. 1 and 2;

FIG. 21 is a fragmentary cross sectional elevation view illustrating the semiconductor substrate in a step, subsequent to the step of FIG. 20, involved in the method of forming the semiconductor device of FIGS. 1 and 2;

FIG. 22 is a fragmentary cross sectional elevation view illustrating the semiconductor substrate in a step, subsequent to the step of FIG. 21, involved in the method of forming the semiconductor device of FIGS. 1 and 2;

FIG. 23 is a fragmentary cross sectional elevation view illustrating the semiconductor substrate in a step, subsequent to the step of FIG. 22, involved in the method of forming the semiconductor device of FIGS. 1 and 2;

FIG. 24 is a fragmentary cross sectional elevation view illustrating the semiconductor substrate in a step, subsequent to the step of FIG. 23, involved in the method of forming the semiconductor device of FIGS. 1 and 2;

FIG. 25 is a fragmentary cross sectional elevation view illustrating the semiconductor substrate in a step, subsequent to the step of FIG. 24, involved in the method of forming the semiconductor device of FIGS. 1 and 2;

FIG. 26 is a fragmentary cross sectional elevation view illustrating the semiconductor substrate in a step, subsequent to the step of FIG. 25, involved in the method of forming the semiconductor device of FIGS. 1 and 2;

FIG. 27 is a fragmentary cross sectional elevation view illustrating the semiconductor substrate in a step, subsequent to the step of FIG. 26, involved in the method of forming the semiconductor device of FIGS. 1 and 2;

FIG. 28 is a fragmentary cross sectional elevation view illustrating the semiconductor substrate in a step, subsequent to the step of FIG. 27, involved in the method of forming the semiconductor device of FIGS. 1 and 2;

FIG. 29 is a fragmentary cross sectional elevation view illustrating the semiconductor substrate in a step, subsequent to the step of FIG. 28, involved in the method of forming the semiconductor device of FIGS. 1 and 2;

FIG. 30 is a fragmentary cross sectional elevation view illustrating the semiconductor substrate in a step, subsequent to the step of FIG. 29, involved in the method of forming the semiconductor device of FIGS. 1 and 2;

FIG. 31 is a fragmentary cross sectional elevation view illustrating a semiconductor substrate in a step involved in a method of forming a semiconductor device in accordance with a second preferred embodiment of the present invention;

FIG. 32 is a fragmentary cross sectional elevation view illustrating the semiconductor substrate in a step, subsequent to the step of FIG. 31, involved in the method of forming the semiconductor device in accordance with the second preferred embodiment of the present invention;

FIG. 33 is a fragmentary cross sectional elevation view illustrating the semiconductor substrate in a step, subsequent to the step of FIG. 32, involved in the method of forming the semiconductor device in accordance with the second preferred embodiment of the present invention;

FIG. 34 is a fragmentary cross sectional elevation view illustrating a semiconductor substrate in a step involved in a method of forming a semiconductor device in accordance with a third preferred embodiment of the present invention;

FIG. 35 is a fragmentary cross sectional elevation view illustrating the semiconductor substrate in a step, subsequent to the step of FIG. 32, involved in the method of forming the semiconductor device in accordance with the third preferred embodiment of the present invention;

FIG. 36 is a fragmentary cross sectional elevation view illustrating the semiconductor substrate in a step, subsequent to the step of FIG. 35, involved in the method of forming the semiconductor device in accordance with the third preferred embodiment of the present invention;

FIG. 37 is a fragmentary cross sectional elevation view illustrating the semiconductor substrate in a step, subsequent to the step of FIG. 36, involved in the method of forming the semiconductor device in accordance with the third preferred embodiment of the present invention;

FIG. 38 is a fragmentary cross sectional elevation view illustrating the semiconductor substrate in a step, subsequent to the step of FIG. 37, involved in the method of forming the semiconductor device in accordance with the third preferred embodiment of the present invention;

FIG. 39 is a fragmentary cross sectional elevation view illustrating a semiconductor substrate in a step involved in a method of forming a semiconductor device in accordance with a fourth preferred embodiment of the present invention;

FIG. 40 is a fragmentary cross sectional elevation view illustrating the semiconductor substrate in a step, subsequent to the step of FIG. 39, involved in the method of forming the semiconductor device in accordance with the fourth preferred embodiment of the present invention;

FIG. 41 is a fragmentary cross sectional elevation view illustrating the semiconductor substrate in a step, subsequent to the step of FIG. 40, involved in the method of forming the semiconductor device in accordance with the fourth preferred embodiment of the present invention;

FIG. 42 is a fragmentary cross sectional elevation view illustrating a semiconductor substrate in a step involved in a method of forming a semiconductor device in accordance with a fifth preferred embodiment of the present invention;

FIG. 43 is a fragmentary cross sectional elevation view illustrating the semiconductor substrate in a step, subsequent to the step of FIG. 42, involved in the method of forming the semiconductor device in accordance with the fifth preferred embodiment of the present invention;

FIG. 44 is a fragmentary cross sectional elevation view illustrating the semiconductor substrate in a step, subsequent to the step of FIG. 43, involved in the method of forming the semiconductor device in accordance with the fifth preferred embodiment of the present invention;

FIG. 45 is a fragmentary cross sectional elevation view illustrating the semiconductor substrate in a step, subsequent to the step of FIG. 43, involved in the method of forming the semiconductor device in accordance with the fifth preferred embodiment of the present invention;

FIG. 46 is a fragmentary cross sectional elevation view illustrating a semiconductor substrate in a step involved in a method of forming a semiconductor device in accordance with a sixth preferred embodiment of the present invention;

FIG. 47 is a fragmentary cross sectional elevation view illustrating the semiconductor substrate in a step, subsequent to the step of FIG. 46, involved in the method of forming the semiconductor device in accordance with the sixth preferred embodiment of the present invention;

FIG. 48 is a fragmentary cross sectional elevation view illustrating the semiconductor substrate in a step, subsequent to the step of FIG. 47, involved in the method of forming the semiconductor device in accordance with the sixth preferred embodiment of the present invention;

FIG. 49 is a fragmentary cross sectional elevation view illustrating the semiconductor substrate in a step, subsequent to the step of FIG. 48, involved in the method of forming the semiconductor device in accordance with the sixth preferred embodiment of the present invention;

FIG. 50 is a fragmentary cross sectional elevation view illustrating the semiconductor substrate in a step, subsequent to the step of FIG. 49, involved in the method of forming the semiconductor device in accordance with the sixth preferred embodiment of the present invention; and

FIG. 51 is a schematic perspective view illustrating a semiconductor device in the related art.

### DETAILED DESCRIPTION OF THE INVENTION

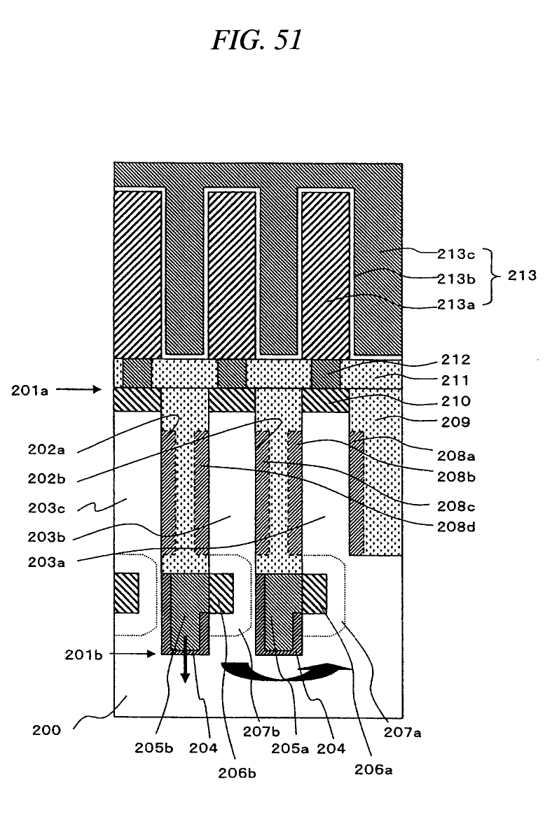

Before describing the present invention, the related art will be explained in detail with reference to FIG. 51, in order to facilitate the understanding of the present invention.

FIG. 51 shows, in a cross-sectional view, an outline of the vertical-type transistor in a memory cell of a DRAM (Dynamic Random Access Memory) disclosed in Japanese Unexamined Patent Application Publication No. 2009-10366. Trenches 202a and 202b of which the bottom face is indicated as 201b are formed in a semiconductor substrate 200 made of silicon having a surface 201a. A region between the trenches includes silicon pillars 203a, 203b, and 203c used as channels of the transistor. A pair of buried gate electrodes 208a and 208b are formed in both sidewalls of the silicon pillar 203a, and a pair of buried gate electrodes 208c and 208d are formed in both sidewalls of the silicon pillar 203b adjacent thereto. The gate electrodes perform as a word line.

The buried bit lines 205a and 205b are formed in the bottom of the trench through a thermally-oxidized film 204. When the semiconductor device of FIG. 51 is seen in a plan view, the extension direction of the bit line is a direction perpendicular to the extension direction of the word line. The buried bit lines 205a and 205b are connected to diffusion layers 206a and 206b, respectively, formed in the semiconductor substrate 200, which make up one of source/drain regions of the transistor. A diffusion layer 210 which makes up the other of the source and drain regions of the transistor is formed on the upper portion of each silicon pillar. A capacitor 213 is formed on the diffusion layer 210 through a contact plug 212. The capacitor 213 is composed of a lower electrode 213a, a capacitive insulation film 213b, and an upper electrode 213c.

Each of the silicon pillars and the contact plug is insulated and separated by interlayer insulation films 209 and 211. Focusing on the silicon pillar 203b, one vertical-type transistor is composed of the diffusion layer 206b, connected to the bit line 205b, which makes up one of the source and drain regions, a pair of gate electrodes 208c and 208d formed in both sidewalls of the pillar, and the diffusion layer 210, connected to the capacitor, which makes up the other of the source and drain regions.

As seen from the above, the vertical-type transistor is constituted such that it is different from the planar-type transistor, the pillar is formed in a direction perpendicular to a main surface of the semiconductor substrate, and the channel is formed within this pillar in a direction perpendicular to the principal surface at the time of turn-ON. This vertical-type transistor can be effectively applied to the semiconductor memory element represented by the miniaturized DRAM.

However, with the development of miniaturization, the required bit line width becomes smaller. For this reason, the trench width for the bit line also becomes smaller, and in the thermal oxidation process stated in the above-mentioned (2) “after the inner wall of the trench is thermally-oxidized, the bit line is formed within the trench by a CVD method”, it is difficult to uniformly thermally-oxidize the inner wall of the trench. In particular, the aspect ratio (ratio of the width to the depth) of the trench becomes relatively larger as the width of the trench becomes smaller, and the amount of oxygen reaching the bottom face of the inner wall of the trench at the time of thermal oxidation becomes smaller than the amount of oxygen reaching the lateral face of the inner wall of the trench. As a result, the thickness of an oxide film formed in the bottom face of the inner wall of the trench through thermal oxidation is smaller than the thickness of an oxide film formed on the lateral face of the inner wall of the trench. For this reason, there has been a problem that when the voltage is applied to the bit line, the current is leaked (shown in the down arrow of FIG. 51) to the semiconductor substrate due to a shortage of the dielectric strength voltage of the bit line and the semiconductor substrate. In addition, there has been a problem that the adjacent bit lines are short-circuited (shown in the horizontal arrow of FIG. 51) due to the stretching of depletion layers (207a, 207b) from the diffusion layers (206a, 206b) connected to the bit line.

Consequently, in order to prevent the oxide film on the bottom face of the inner wall of the trench from being thinned like this, it is possible to thicken the oxide film itself on the bottom face of the inner wall of the trench by controlling the conditions of thermal oxidation. However, in this case, the thickness of the oxide film on the lateral face of the inner wall of the trench is also equal to or more than the thickness of the insulation film on the bottom face, and a space within the trench decreases. Thereby, there has been a problem that the aspect ratio of the trench becomes large, and a plurality of thin films cannot be formed in the space within the trench in a subsequent process.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a method of forming a semiconductor device may include, but is not limited to, the following processes. A groove is formed in a semiconductor substrate. A first insulating film is formed on a bottom surface of the groove and a second insulating film on a side surface of the groove. The second insulating film is thinner than the first insulating film. A conductive layer is formed on the first insulating film.

In some cases, forming the second insulating film on the side surface of the groove may include, but is not limited to, thermally oxidizing the side surface of the groove.

In some cases, forming the groove in the semiconductor substrate may include, but is not limited to, forming a trench groove in the semiconductor substrate. Forming the conductive layer may include, but is not limited to, forming a bit line on the first insulating film.

In some cases, forming the groove in the semiconductor substrate may include, but is not limited to, forming the groove in a silicon substrate.

In some cases, forming the first insulating film and the second insulating film may include, but is not limited to, the following processes. The bottom surface of the groove and the side surface of the groove are thermally oxidized to form a silicon oxide film on the bottom surface of the groove and the side surface of the groove. A silicon film is formed, which fills the groove. The silicon oxide film and the silicon film are selectively removed to have the silicon oxide film and the silicon film reside on the bottom surface of the groove. The silicon film is removed to form the first insulating film on the bottom surface of the groove. The side surface of the groove are thermally oxidized to form the second insulating film on the side surface of the groove.

In some cases, forming the first insulating film and the second insulating film may include, but is not limited to, the following processes. Oxygen is introduced into the silicon substrate through the groove to form an oxygen-introduced region under the bottom surface of the groove. The bottom surface of the groove and the side surface of the groove are thermally oxidized to form the first insulating film on the bottom surface of the groove and the second insulating film on the side surface of the groove.

In some cases, forming the first insulating film and the second insulating film may include, but is not limited to, the following processes. The bottom surface of the groove and the side surface of the groove are thermally oxidized to form a silicon oxide film on the bottom surface of the groove and the second insulating film on the side surface of the groove. A silicon nitride film is formed which covers the silicon oxide film on the bottom surface of the groove. The silicon oxide film on the bottom surface of the groove while the silicon nitride film covering the side surface of the groove are thermally oxidized to increase a thickness of the silicon oxide film to form the first insulating film on the bottom surface of the groove.

In some cases, forming the first insulating film and the second insulating film further may include, but is not limited to, removing the silicon nitride film.

In some cases, forming the first insulating film and the second insulating film may include, but is not limited to, the following processes. The bottom surface of the groove and the side surface of the groove are thermally oxidized to form a silicon oxide film on the bottom surface of the groove and the second insulating film on the side surface of the groove. A high density plasma chemical vapor deposition is performed to form an additional silicon oxide film on the silicon oxide film on the bottom surface of the groove. The additional silicon oxide film is selectively removed to form the first insulating film on a bottom surface of the groove. The first insulating film may include, but is not limited to, the silicon oxide film and the additional silicon oxide film.

In some cases, forming the first insulating film and the second insulating film may include, but is not limited to, the following processes. The bottom surface of the groove and the side surface of the groove are thermally oxidized to form a silicon oxide film on the bottom surface of the groove and the side surface of the groove. A silicate glass is formed which fills the groove. The silicon oxide film and the silicate glass are selectively removed to form the first insulating film on the bottom surface of the groove. The first insulating film may include, but is not limited to, the silicon oxide film and the silicate glass. The side surface of the groove is thermally oxidized to form the second insulating film on the side surface of the groove.

In some cases, forming the first insulating film and the second insulating film may include, but is not limited to, the following processes. Oxygen is introduced into the silicon substrate through the groove to form an oxygen-introduced region under the bottom surface of the groove. The bottom surface of the groove and the side surface of the groove are thermally oxidized to form a silicon oxide film on the bottom surface of the groove and the second insulating film on the side surface of the groove. A silicate glass is formed, which fills the groove. The silicon oxide film and the silicate glass are selectively removed to form the first insulating film on the bottom surface of the groove. The first insulating film may include, but is not limited to, the silicon oxide film and the silicate glass. The side surface of the groove is thermally oxidized to form the second insulating film on the side surface of the groove.

In some cases, the method of forming the semiconductor device may include, but is not limited to, the following processes. A contact layer is formed on a selected region of the side surface of the groove. A diffusion layer is formed in the semiconductor substrate. The diffusion layer is adjacent to the selected region of the side surface of the groove. The diffusion layer contacts the contact layer. Forming the conductive layer may include, but is not limited to, forming the conductive layer which contacts the first insulating film and the contact layer.

In some cases, forming the contact layer on the selected region of the side surface of the groove may include, but is not limited to, the following processes. A side wall protection film is formed, which covers the second insulating film on the side surface of the groove. The side wall protection film is over the first insulating film on the bottom surface of the groove. The first insulating film and the second insulating film below the side wall protection film are selectively removed to expose the selected region of the side surface of the groove. The contact layer is formed on the selected region of the side surface of the groove. The contact layer is under the side wall protection film and the second insulating film and over the first insulating film.

In some cases, forming the diffusion layer may include, but is not limited to, thermally diffusing an impurity from the contact layer into the semiconductor substrate through the selected region of the side surface of the groove.

In some cases, forming the first insulating film may include, but is not limited to, forming the first insulating film having a thickness in the range of 6 nm to 60 nm.

In some cases, forming the second insulating film may include, but is not limited to, forming the second insulating film having a thickness in the range of 1 nm to 5 nm.

In another embodiment, a method of forming a semiconductor device may include, but is not limited to, the following processes. A groove is formed in a silicon substrate. A first insulating film is formed on a bottom surface of the groove and a second insulating film on a side surface of the groove. At least the second insulating film is formed by thermal oxidation. The second insulating film is thinner than the first insulating film. The first insulating film and the second insulating film are selectively removed to expose a selected region of the side surface of the groove. A contact layer is formed on the selected region of the side surface of the groove. An impurity is thermally diffused from the contact layer into the semiconductor substrate through the selected region of the side surface of the groove to form a diffusion layer in the semiconductor substrate. The diffusion layer is adjacent to the selected region of the side surface of the groove. The diffusion layer contacts the contact layer. A conductive layer is formed on the first insulating film.

In some cases, forming the first insulating film may include, but is not limited to, thermally oxidizing the bottom surface of the groove.

In some cases, forming the first insulating film may include, but is not limited to, performing a high density plasma chemical vapor deposition.

In still another embodiment, a method of forming a semiconductor device may include, but is not limited to, the following processes. A trench groove is formed in a silicon substrate. A bottom surface of the groove is thermally oxidized to form a first insulating film on the bottom surface of the groove. A side surface of the groove is thermally oxidized to form the second insulating film on the side surface of the groove. The second insulating film is thinner than the first insulating film. A bit line is formed on the first insulating film.

A trench formed within a semiconductor substrate in a bit line extension direction includes a first region in which a bit line is formed at the bottom of the trench, and a second region located above the bit line. That is, a region of the trench located below the upper surface of the bit line, which is rectangular in shape when seen in a cross-sectional view (cross-sectional view similar to FIG. 51), is the first region, and a region of the trench located above the upper surface of the bit line is the second region. In addition, in the first region, an insulation film interposed between the bottom face of the bit line and the bottom face of the trench opposite to the bottom face of the bit line is the first insulation film, and in the second region, a thermally-oxidized film formed in the inner wall of the trench by a thermal oxidation method is the second insulation film. Therefore, although the second insulation film is formed of a thermally-oxidized film, the first insulation film is not limited to the thermally-oxidized film, but may be an insulation film formed by other film formation methods, and may be a laminated film thereof. In addition, the bit line does not contact the second insulation film directly.

In the method of forming the semiconductor device of the embodiment of the invention, among processes leading to the formation of the bit line, the second insulation film formed in the second region is smaller in film thickness than the first insulation film formed in the first region. That is, it is possible to make the thickness of the second insulation film smaller than the thickness of the first insulation film while maintaining the film thickness at which a leakage current is not generated in the first insulation film at a step in which the semiconductor device is completed.

As a result, it is possible to avoid the generation of the leakage current between the bottom face of the bit line and the semiconductor substrate at the step in which the semiconductor device is completed. In addition, it is possible to avoid the problem of being incapable of forming a plurality of thin films by a reduction in a trench space of the second region among processes leading to the formation of the bit line.

The first insulation film preferably has a film thickness of 6 nm to 60 nm. When the film thickness is less than 6 nm, there may be a case that the effect of suppressing the leakage current is insufficient. In addition, when the film thickness is more than 60 nm, the trench has to be formed relatively deeply, and thus there may be a case that the trench itself has a high aspect ratio, resulting in difficult groove working. The reason for the working becoming difficult like this is that, in a vertical-type transistor, a gate electrode formed above the bit line does not allow for dimensional variability for the purpose of constantly securing the characteristics of the transistor. For this reason, other dimensional variability has to be regulated by adjusting the depth of the initially formed trench. Therefore, an increase in the excess film thickness of the first insulation film causes the trench to be formed with a greater depth, and thus the workability in the trench formation is lowered.

The second insulation film preferably has a film thickness of 1 nm to 5 nm. There may be a case in which the semiconductor substrate of the trench sidewall cannot be protected when the film thickness is less than 1 nm. When the film thickness is greater than 5 nm, among processes leading to the formation of the bit line, the trench space of the second region is reduced and thus a plurality of thin films cannot be formed. As a result, there may be a case that the bit line itself cannot be formed.

Typical examples of a technical idea to solve the problem of the embodiment of the invention will be shown hereinafter. However, the claimed contents of the present application are not limited to this technical idea, and it is needless to say that the contents are the contents stated in the claims of the present application.

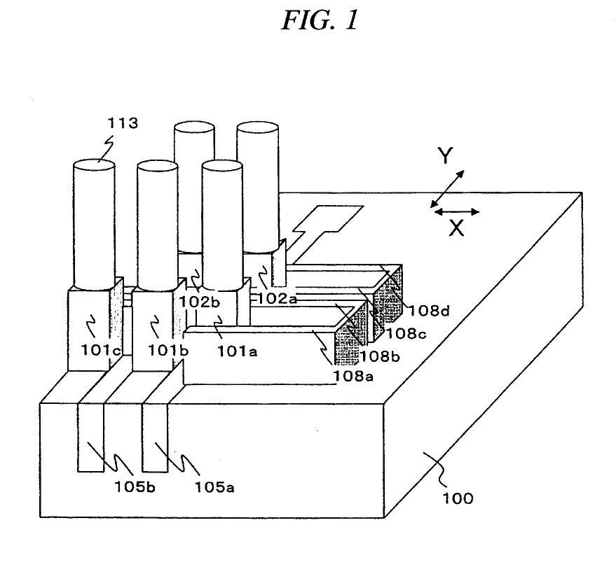

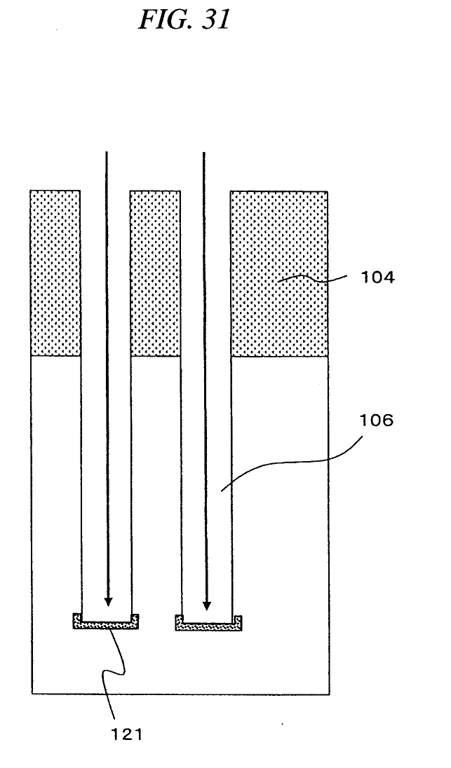

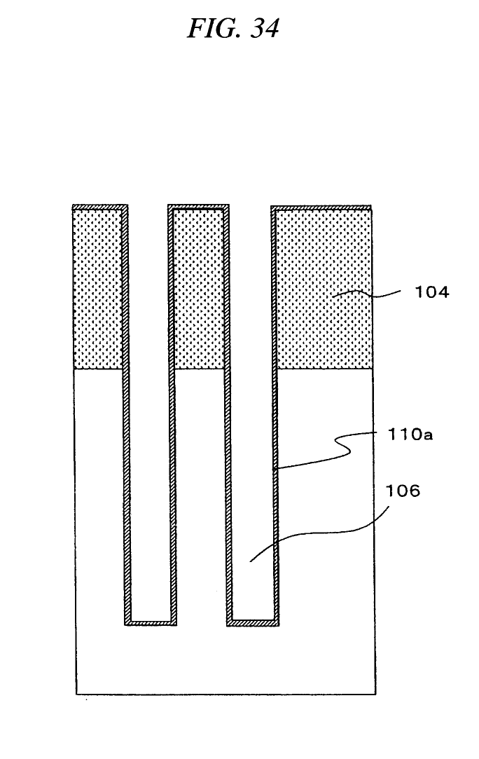

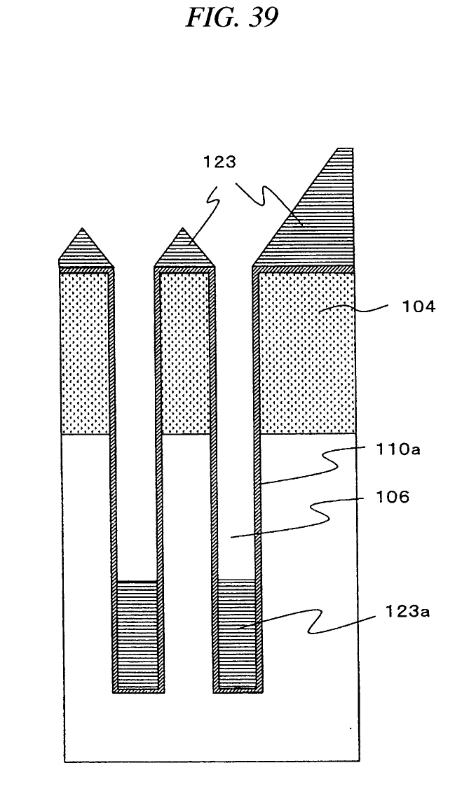

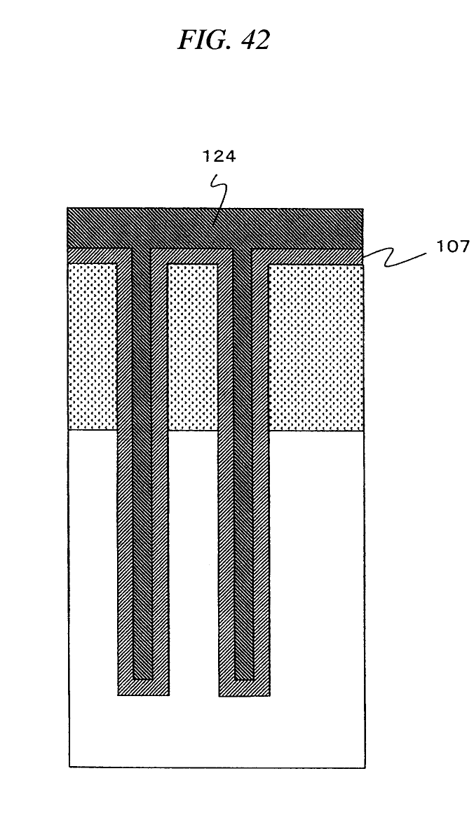

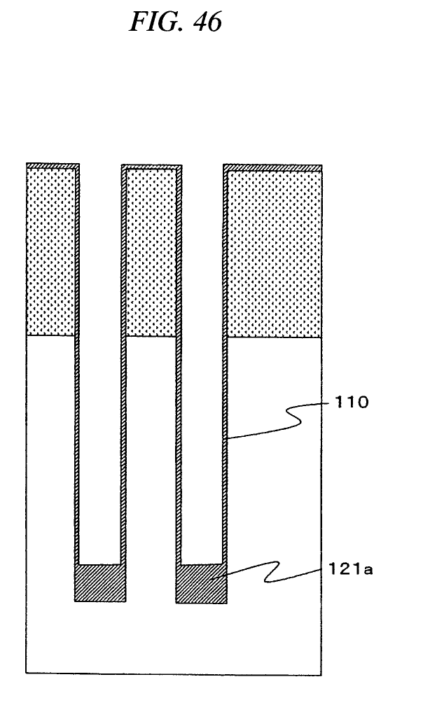

FIGS. 1 to 50 are cross-sectional views illustrating a series of processes for forming up to the buried bit line of the semiconductor device according to the embodiment. FIGS. 1 to 30 refer to a first embodiment. FIGS. 31 to 33 refer to a second embodiment. FIGS. 34 to 38 refer to a third embodiment. FIGS. 39 to 41 refer to a fourth embodiment. FIGS. 42 to 45 refer to a fifth embodiment. FIGS. 46 to 50 refer to a sixth embodiment.

### FIRST EMBODIMENT

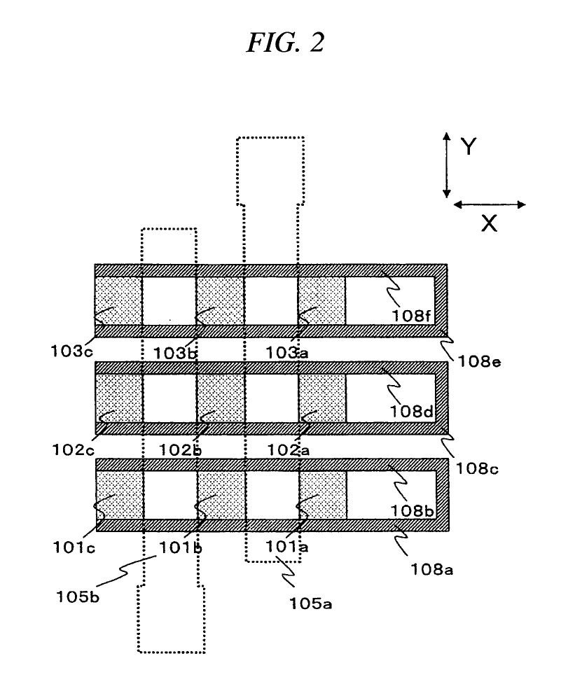

Initially, an outline of the semiconductor device to which the embodiment of the invention is applied will be described taking a DRAM as an example, with reference to FIGS. 1 and 2. FIG. 1 is a perspective view schematically illustrating the memory cell portion of the DRAM. FIG. 2 is a plan view corresponding to FIG. 1.

First, reference is made to FIG. 1. Capacitors 113 are formed on silicon pillars 101a, 101b, 101c, 102a, and 102b which are dug into a semiconductor substrate 100 made of silicon. Word lines 108a, 108b, 108c and 108d (only a portion of the word line 108a is shown in FIG. 1), and bit lines 105a and 105b included in the gate electrode of the transistor are formed by extending at different heights and in a vertical direction so as to surround the silicon pillar. That is, each of the word lines extends in the X direction at a position higher than that of the bit line, and each of the bit lines is formed in the innermost section of the trench and extends in the Y direction perpendicular to the X direction.

The transistors included in a unit cell are connected to one bit line and two word lines. For example, the transistor having the silicon pillar 101a is connected to the bit line 105a, and is connected to a pair of word lines 108a and 108b at the cell region end. Similarly, the transistor having the silicon pillar 102a is connected to the bit line 105a and a pair of word lines 108c and 108d. The same is true of the transistors having the other silicon pillars.

Since the word lines 108b and 108c are separated from each other by an insulation film, the transistor of FIG. 1 is a double-gate type in which two word lines are formed on one pillar, but on the other hand the bit line is connected only to the one-sided silicon pillar. That is, the bit line is connected to a diffusion layer formed within the silicon pillar by opening only an insulation film of the silicon pillar side to be connected. Therefore, the bit line is not connected to one silicon pillar (silicon pillar on the side opposite to the side to which the bit line is connected) by an insulation film (silicon oxide film) formed on the lateral face of the silicon pillar. In addition, the bottom face of the bit line is insulated from the silicon substrate by the insulation film. The basic configuration of this part is the same as that of FIG. 51 used in the description of the background art.

Reference is made to FIG. 2. In the memory cell according to the embodiment, the silicon pillars 101a, 101b, 101c, 102a, 102b, 102c, 103a, 103b, and 103c are regularly disposed in the X direction and the Y direction perpendicular to the X direction. In FIG. 2, nine silicon pillars are shown for convenience of description, but are not limited thereto, and in practice thousands to hundreds of thousands of silicon pillars are disposed. Therefore, the number of hundreds to thousands of orders of the bit lines and the word lines exists as well. The bit lines 105a and 105b extending in the Y direction are formed between each of the silicon pillars disposed in the X direction. Each of the bit lines is shared by a plurality of silicon pillars disposed in the Y direction. For example, the bit line 105a is shared by the silicon pillars 101a, 102a, and 103a. Similarly, the other bit lines are also shared among a plurality of silicon pillars.

A method of forming the bit line within the semiconductor device shown in FIGS. 1 and 2 will be described. First, a silicon nitride film 104 having a thickness of 160 nm or so is formed on the silicon substrate by a decompression CVD (Chemical Vapor Deposition) method which is set to the following film formation conditions.

Raw material gas and flow rate: dichlorosilane (SiH₂Cl₂)/ammonia (NH₃)=75/750 sccm

Heating temperature: 630° C.

Pressure: 300 Pa.

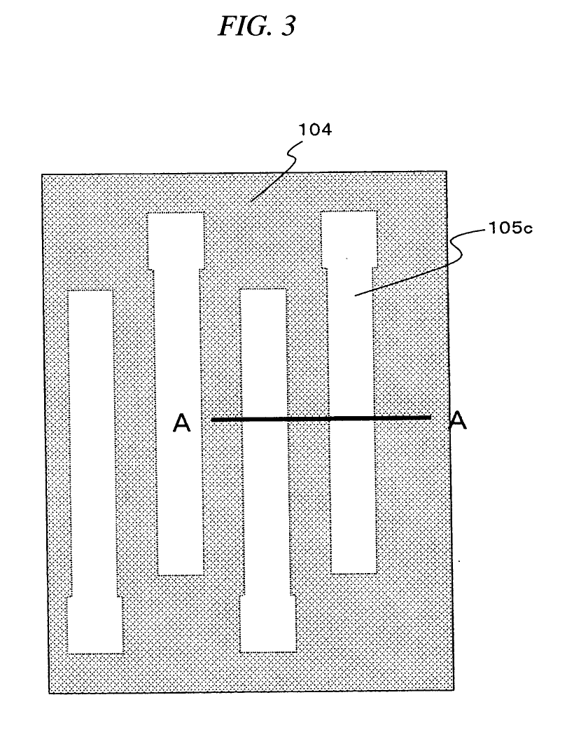

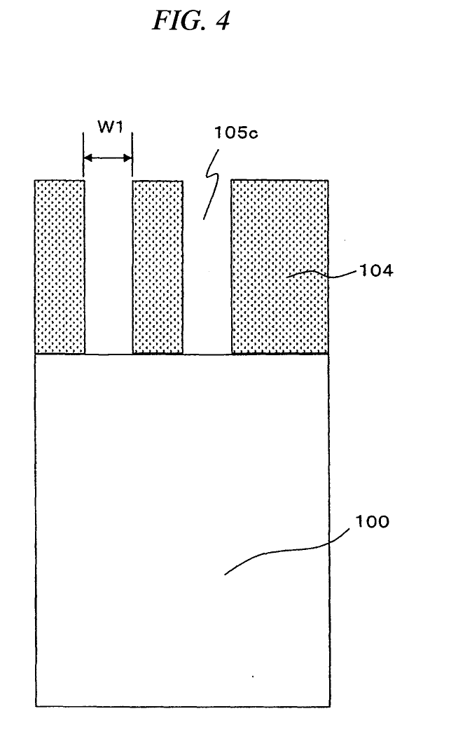

As shown in a plan view of FIG. 3, a bit line opening 105c extending in the Y direction is formed within the silicon nitride film 104 by photolithography and dry etching. FIG. 4 is a diagram showing an A-A cross section of FIG. 3. The silicon substrate 100 is exposed in the bottom of the opening 105c. In the embodiment, the width W1 of the opening 105c is set to 45 nm.

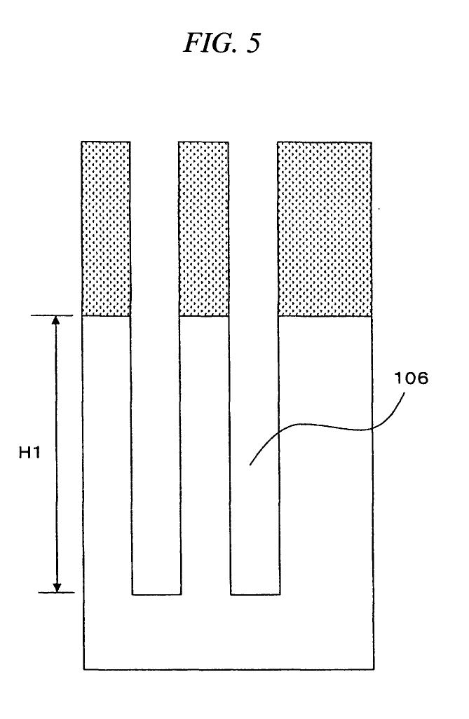

As shown in FIG. 5, anisotropic dry etching is performed on the silicon substrate 100 using the silicon nitride film 104 as a mask, and a trench 106 having a depth H1 of 300 nm is formed. In this dry etching, a RIE (Reactive Ion Etching) method using ICP (Inductively Coupled Plasma), which is set to the following conditions, is employed.

Source power: 1000 W

High-frequency power: 50 W to 200 W

Pressure: 5 to 20 mTorr

Stage temperature: 20° C. to 40° C.

Etching gas and flow rate: sulfur hexafluoride (SF₆) [90 sccm], chlorine (Cl₂) [100 sccm].

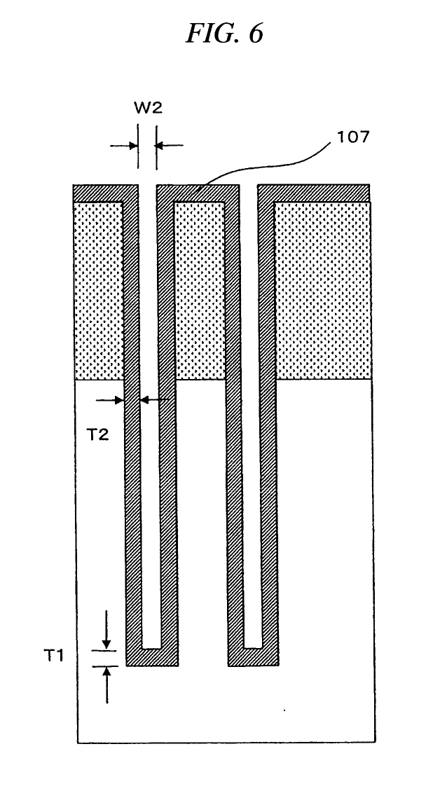

As shown in FIG. 6, a silicon oxide film 107 is formed so that the film thickness T1 in the bottom face of the trench 106 is set to 10 nm by a thermal oxidation method using a heating temperature of 800° C. to 900° C. In the embodiment, the portion of the silicon oxide film 107 formed in the bottom face of the trench 106 by the thermal oxidation method corresponds to the first insulation film. In thermal oxidation of the inner surface of the trench, a concentration difference is generated in oxidation species within the trench. That is, since oxygen which is an oxidation species is less concentrated in the vicinity of the bottom face of the trench 106, the film thickness T1 of the silicon oxide film 107 on the bottom face of the trench 106 is smaller than the film thickness T2 of the silicon oxide film 107 formed on the lateral face thereof. According to experiments by the inventor, it is obvious that this phenomenon is conspicuously generated when an aspect ratio of the trench exceeds 8.

In the embodiment, since the film thickness of the silicon nitride film 104 used as a mask is 160 nm and the etching depth H1 of the silicon substrate is 300 nm, resulting in a total depth of 460 nm, and the width W1 of the opening is 45 nm, an aspect ratio is set to approximately 10 times. As stated above, when the silicon oxide film 107 is formed so as to form a film thickness T1 of 10 nm in the bottom face of the trench 106, the thickness T2 of the silicon oxide film 107 formed on the lateral face of the trench is set to approximately 17 nm. When a silicon oxide film having a thickness of 17 nm is formed on the lateral face within the trench 106 of which the width of the opening is no more than 45 nm, the width W2 of the remaining trench is 11 nm.

Under these circumstances, when a silicon nitride film and the like for protecting the lateral face of the trench, which is required in a later process, are formed, there is a problem in that the trench itself is blocked, so that the bit line cannot be formed.

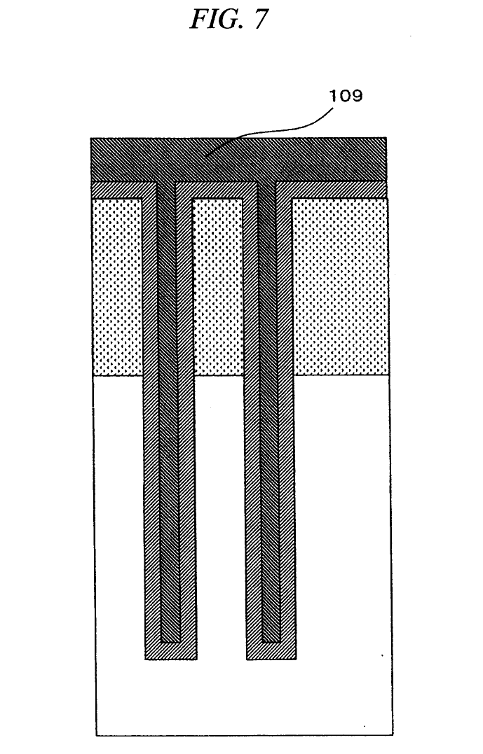

Consequently, in the embodiment, after the silicon oxide film 107 is formed so that the film thickness T1 in the bottom face of the trench 106 is set to 10 nm in FIG. 6, a silicon film 109 is formed in the whole surface by the decompression CVD method so as to fill the inside of the trench, as shown in FIG. 7. Monosilane (SiH₄) is used as a raw material gas at this time.

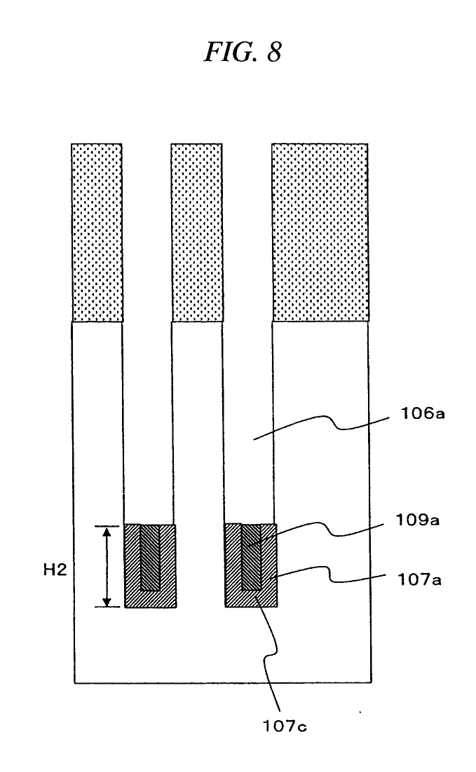

As shown in FIG. 8, anisotropic dry etching is performed on the silicon film 109 and the silicon oxide film 107 under uniform etching conditions, and each of the upper surfaces thereof are etched back up to a position having a height H2 of 50 nm from the bottom face of the trench 106. As a result, positions of each of the upper surfaces are the same, and the silicon oxide film 107a covering the bottom of the trench 106 and the silicon film 109a buried in the inside of the silicon oxide film 107a are formed. As a result, a new trench 106a is formed above the upper surfaces of the silicon oxide film 107a and the silicon film 109a buried in the inside of the silicon oxide film 107a. In this step, the silicon film 109a does not perform as a bit line, but a region of the trench 106 located below the upper surface of the silicon film 109a is equivalent to the first region, and a region of the trench 106a which is newly formed is equivalent to the second region of the trench 106 located above the upper surface of the silicon film 109a. In addition, a portion which is interposed between the bottom face of the bit line and the bottom face of the trench opposite to the bottom face of the bit line, in the silicon oxide film 107a, is equivalent to a first insulation film 107c.

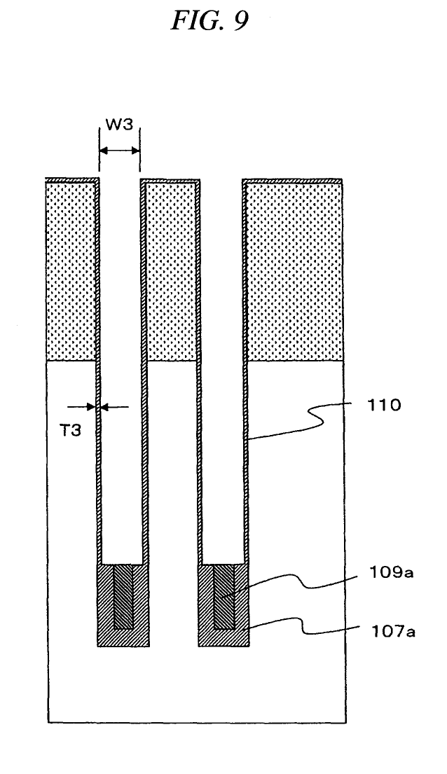

As shown in FIG. 9, a silicon oxide film 110 having a thickness T3 of 3 nm is formed on the lateral face of the trench 106a which is the second region by the thermal oxidation method using a heating temperature of 800° C. to 900° C. In the embodiment, the silicon oxide film 110 having a thickness of 3 nm which is formed by the thermal oxidation method corresponds to the second insulation film. As a result, the opening of the remaining trench 106a having a width W3 of 39 nm is secured.

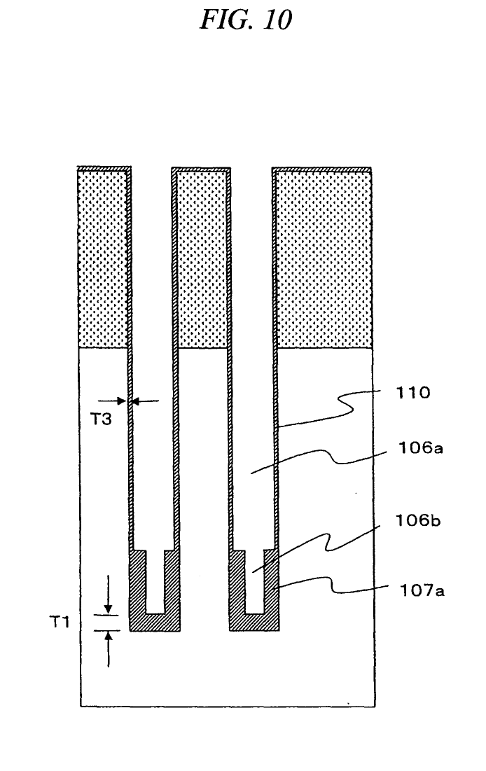

As shown in FIG. 10, the buried silicon film 109a is selectively removed by wet etching using aqueous ammonia (NH₃). In this wet etching, the silicon oxide film is not etched. Therefore, the silicon oxide film 107a formed in the first region remains with a film thickness (T1) of the bottom face maintained at 10 nm. In addition, a new trench 106b is formed by removing the buried silicon film 109a.

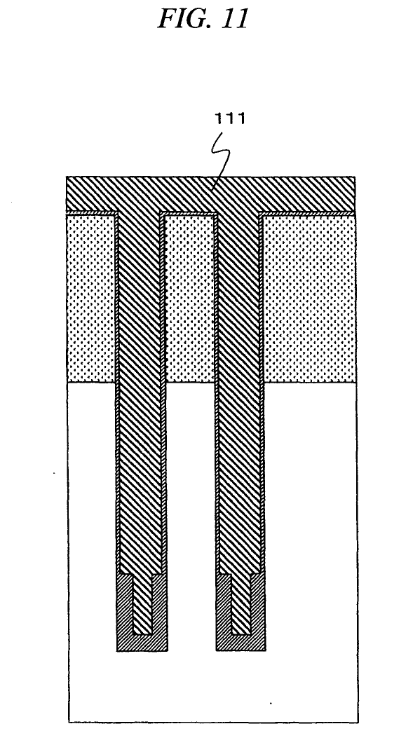

As shown in FIG. 11, an arsenic-doped silicon film 111 is formed in the whole surface so as to fill the trenches 106a and 106b.

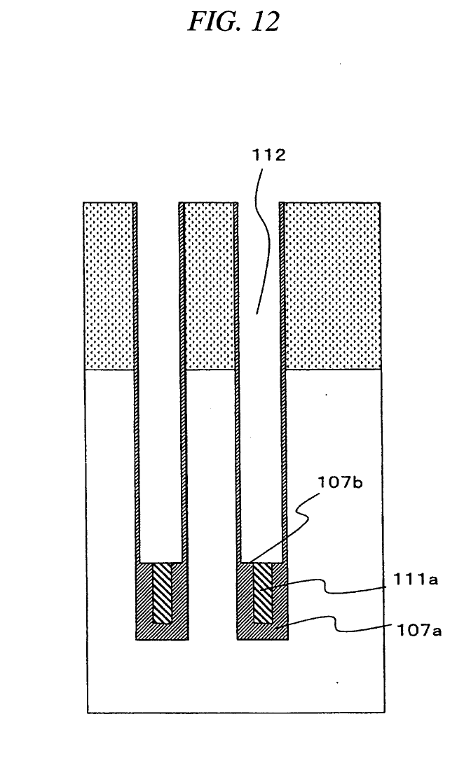

As shown in FIG. 12, the arsenic-doped silicon film 111 is etched back by the anisotropic dry etching, and the trench 106a is filled. Thereby, a new buried film 111a made of the arsenic-doped silicon film 111 is formed which has an upper surface of which the position is the same as that of an upper surface 107b of the silicon oxide film 107a. In addition, a new trench 112 is formed in this step. The opening of the trench 112 having a width of 39 nm is secured.

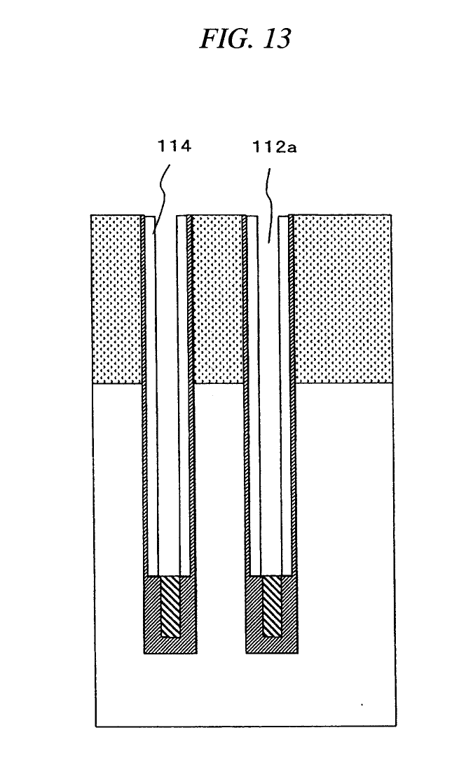

After a silicon nitride film having a thickness of 5 nm is formed in the whole surface including the inner surface of the trench 112 by the CVD method, it is etched back by anisotropic dry etching. As shown in FIG. 13, a sidewall protection film 114 made of the silicon nitride film is then formed. Thereby, the silicon nitride film formed on the mask silicon nitride film 104 and the silicon nitride film formed on the buried film 111a are removed. The sidewall protection film 114 has a role in preventing etching of the silicon oxide film 110 in a later wet etching process. In this step, the trench 112 becomes a new trench 112a, and its opening width is 29 nm.

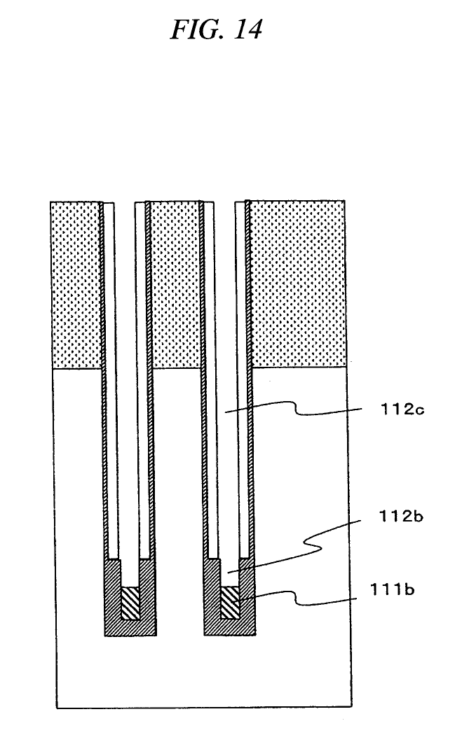

As shown in FIG. 14, the buried film 111a of which the surface is exposed is etched back, and is further dug down by 20 nm. Thereby, the buried film 111a of which the thickness in the vertical direction is 40 nm in the formation step of FIG. 12 becomes a buried film 111b having a thickness of 20 nm. In addition, the dug down region forms a new trench 112b, and forms a trench 112c in conjunction with the trench 112a which has been formed above it.

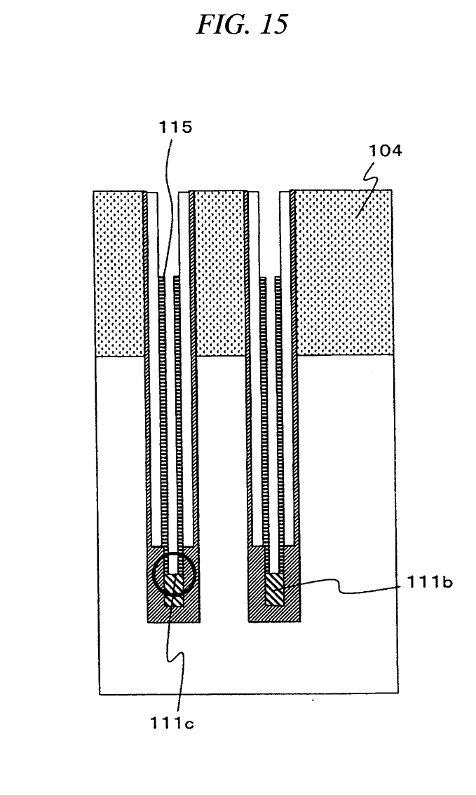

As shown in FIG. 15, a titanium nitride film having a thickness of 7 nm which acts as an etching sacrificial layer is formed over the whole surface by the CVD method. After this, etch back is performed by anisotropic dry etching, and a sidewall 115 is formed on the lateral face of the trench 112c. Thereby, the silicon oxide film 107a exposed on the lateral face of the trench 112b is also coated by the sidewall 115. On the formation of the sidewall 115, the titanium nitride film on an upper surface 111c of the buried film 111b is removed (a portion shown by a black circle in FIG. 15), and simultaneously the upper surface of the sidewall 115 is controlled to be located at a position going down to 70 nm from the upper surface of the mask silicon nitride film 104.

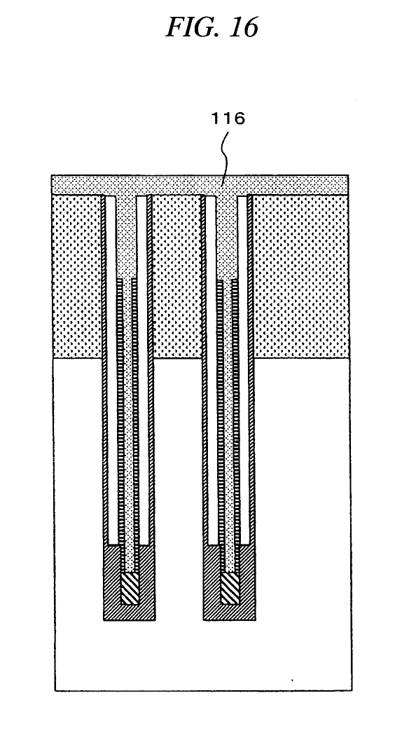

As shown in FIG. 16, a silicon oxide film 116 is formed so as to fill a space remaining within the trench 112c. A CVD method, an ALD (Atomic Layer Deposition) method or a spin-coating method can be used in the silicon oxide film 116.

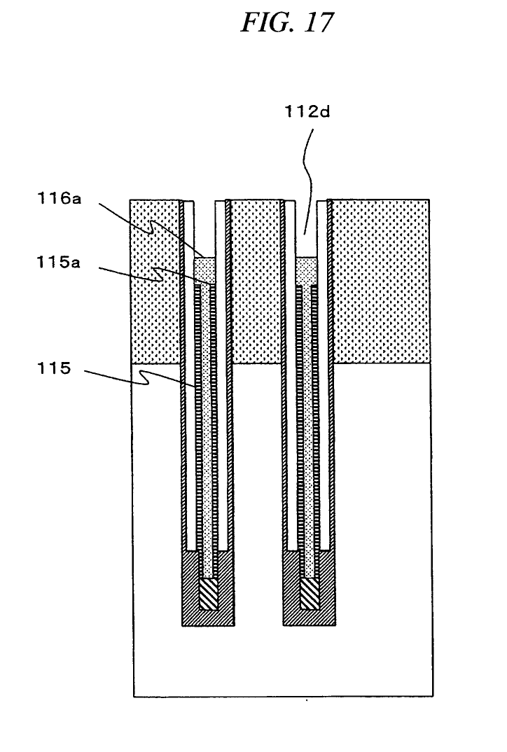

As shown in FIG. 17, by etching back the silicon oxide film 116, a buried silicon oxide film 116a is formed, and simultaneously a trench 112d is formed above it. On the formation of the buried silicon oxide film 116a, the upper surface thereof is formed to be located 50 nm below the upper surface of the mask silicon nitride film 104, and an upper surface 115a of the sidewall made of titanium nitride is controlled not to be exposed. In the embodiment, although a gap in the vertical direction between the upper surface 115a of the sidewall made of titanium nitride and the upper surface of the buried silicon oxide film 116a is set to 20 nm, it may be within a range between 15 and 25 nm. The opening width of the trench 112d is set to 29 nm similarly to the step of FIG. 13.

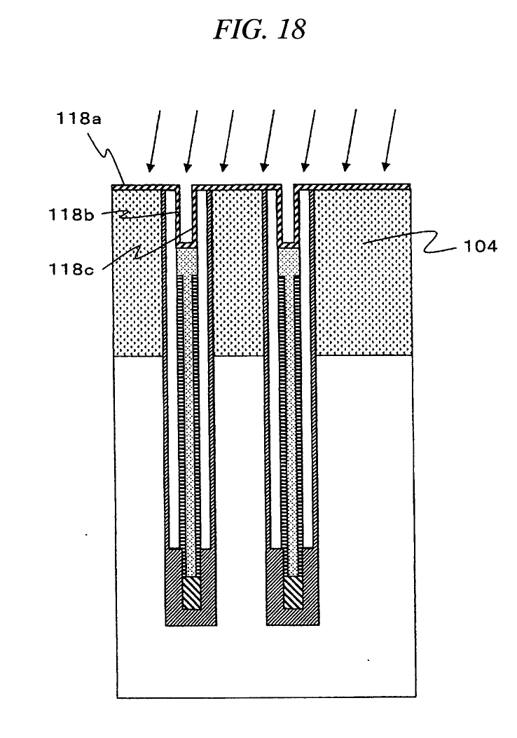

As shown in FIG. 18, a silicon film 118 having a thickness of 5 nm is formed in the whole surface including the inner surface of the trench 112d by the CVD method. The silicon film 118 is preferably an amorphous silicon film which does not affect a crystalline grain causing the generation of nonuniform etching in the etching step. The amorphous silicon film can be obtained by setting the film formation temperature to 540° C. or lower.

After the silicon film 118 is formed, boron fluoride (BF₂) is implanted by an inclined ion implantation method in order to introduce impurities only to a one-sided silicon film in silicon films 118b and 118c formed on the lateral faces of both sides within the trench 112d. Here, an example of implantation into the silicon film 118b is shown. The introduction of impurities is carried out with respect to the silicon film 118 formed on the sidewall on the side opposite to a pillar in which a bit line contact to be described in a later process has to be formed. Thereby, the impurities are implanted into a silicon film 118a formed on the mask silicon nitride film 104, the silicon film 118b, located at the vertical plane, formed on the lateral face of the trench 112d, and a portion (left half) of the silicon film, located at the horizontal plane, formed on the buried silicon oxide film 116a.

Herein, since the ion implantation into both the horizontal plane and the vertical plane is required to be performed, two-step implantation having a different angle may also be used so that optimal ion implantation into each of the implantation sites is performed. In the embodiment, the conditions used are an acceleration energy of 5 keV, an implantation dose amount of 2E14 cm⁻² and an implantation angle of 20° to 30°. Here, the implantation angle means an inclination angle from a perpendicular line with respect to the surface of the semiconductor substrate. In addition, when the above-mentioned two-step implantation is performed in the embodiment, implantation at an implantation angle of 20° and implantation at an implantation angle of 30° are combined. However, the implantation angle can be changed in consideration of the depth or width of the trench 112d, and the thickness of the silicon film 118.

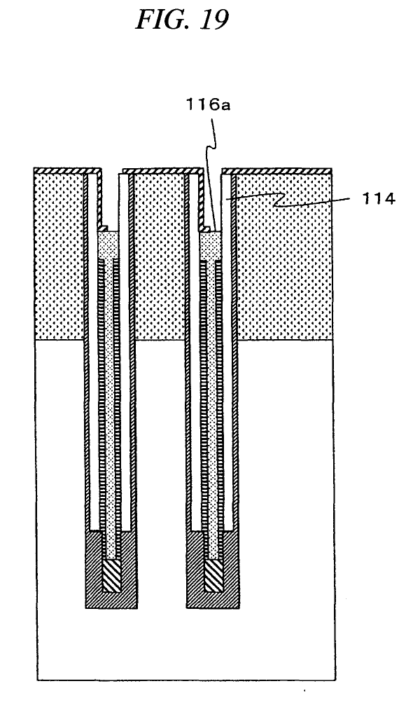

As shown in FIG. 19, the silicon film 118c into which the impurities are not implanted and the silicon film 118 formed in the right half on the buried silicon oxide film 116a are removed by the wet etching using aqueous ammonia (NH₃). Thereby, the sidewall protection film 114 made of a silicon nitride film, and the right half of the buried silicon oxide film 116a are exposed.

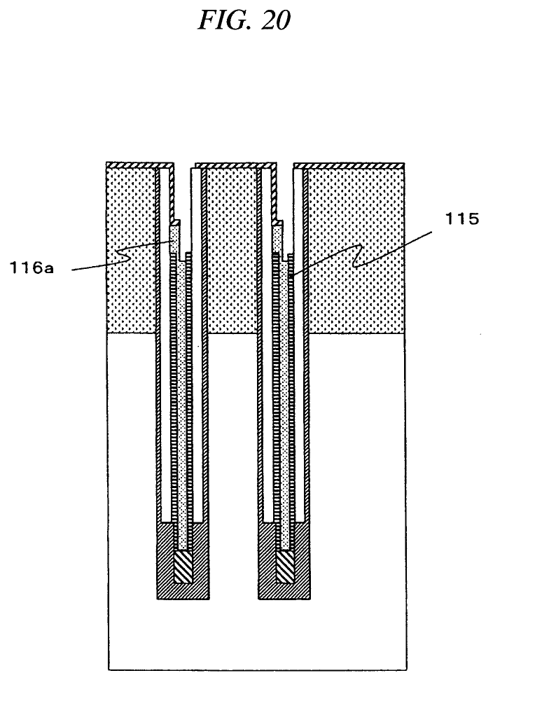

As shown in FIG. 20, using the silicon film 118 as a mask, the anisotropic dry etching is performed on the right half of the buried silicon oxide film 116a which is exposed, and the upper surface of the right sidewall 115 made of a titanium nitride is exposed. At this time, the left sidewall 115 is covered with the buried oxide film 116a and the silicon film 118 and thus is not exposed. Conversely, an impurity introduction region of the ion implantation into the silicon film 118 in FIG. 18 is required to be controlled so that the left sidewall 115 is not exposed by this anisotropic dry etching. That is, the implantation angle is determined in consideration of the depth or width of the trench 112d, and the thickness of the silicon film 118.

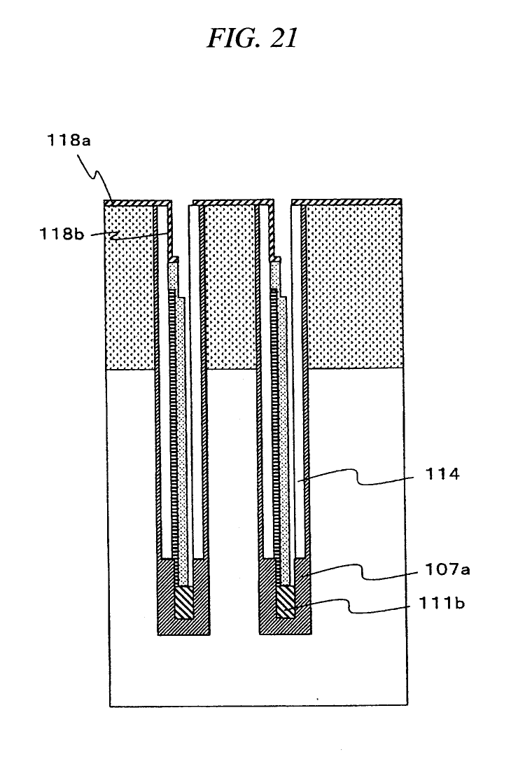

As shown in FIG. 21, the right sidewall 115, which is made of a titanium nitride and of which the upper surface is exposed, is selectively removed by wet etching. A mixed solution and the like of ammonia and hydrogen peroxide water can be used as an etchant. Thereby, the sidewall protection insulation film 114 made of a silicon nitride film, a portion of the silicon oxide film 107a formed in the first region of the trench 106, and a portion of the upper surface of the buried film 111b are exposed.

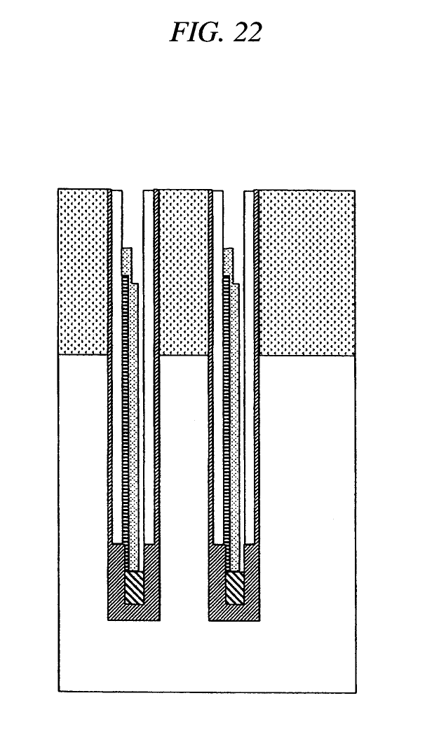

As shown in FIG. 22, the silicon film 118 which is ion-implanted and remains in the substrate surface is removed by isotropic dry etching.

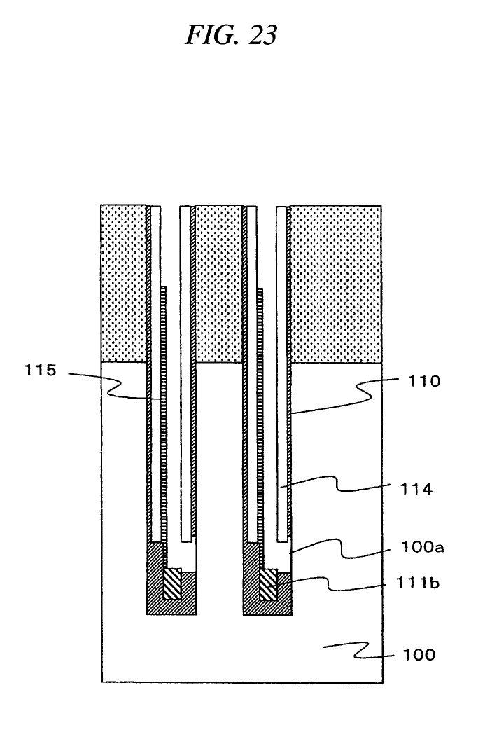

As shown in FIG. 23, the silicon oxide film 107a of which a portion of the lateral face is exposed by a hydrofluoric acid-containing solution is etched, and a lateral opening 100a exposing a portion of the semiconductor substrate 100 is formed. The lateral opening 100a is formed at a position between the bottom face of the sidewall protection insulation film 114 and the upper surface of the buried film 111b. At this time, the buried oxide film 116a is also removed. However, since the second insulation film 110 is protected by the sidewall protection insulation film 114 made of a silicon nitride film, the film is not etched and remains as it is.

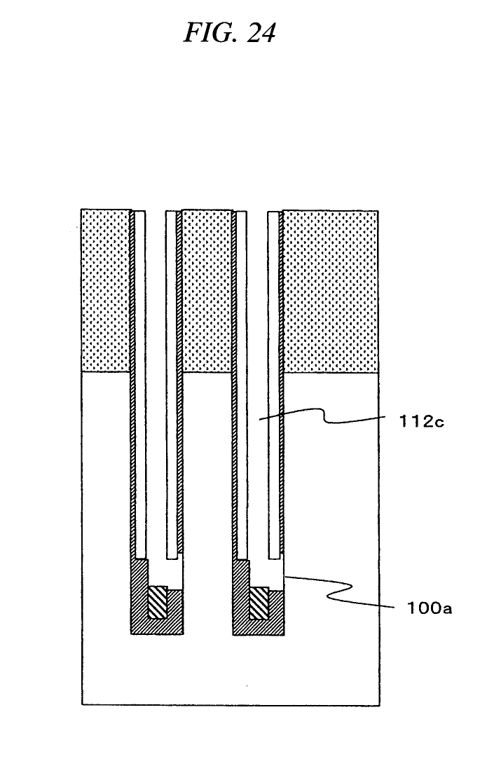

As shown in FIG. 24, the sidewall 115, made of a titanium nitride, which is exposed within the trench is selectively removed. Thereby, the lateral opening 100a is exposed in the trench 112c formed in FIG. 14.

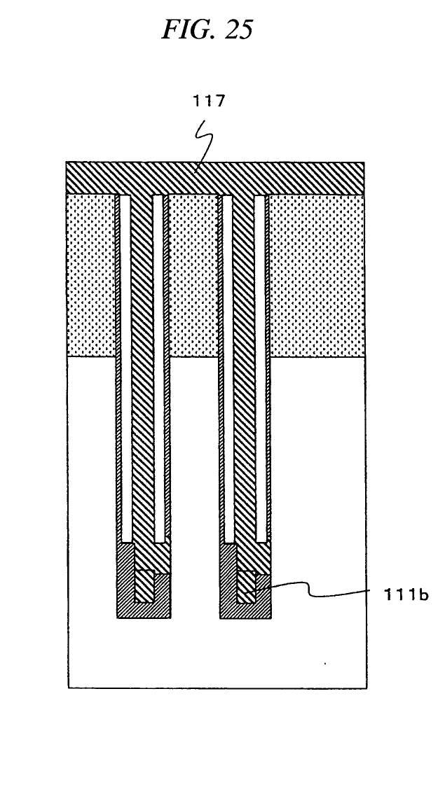

As shown in FIG. 25, an arsenic-doped silicon film 117 is formed in the whole surface by the CVD method so as to fill up the trench 112c. The buried film 111b, which is formed in advance, is also made of an arsenic-doped silicon film, and thus is buried by the same material.

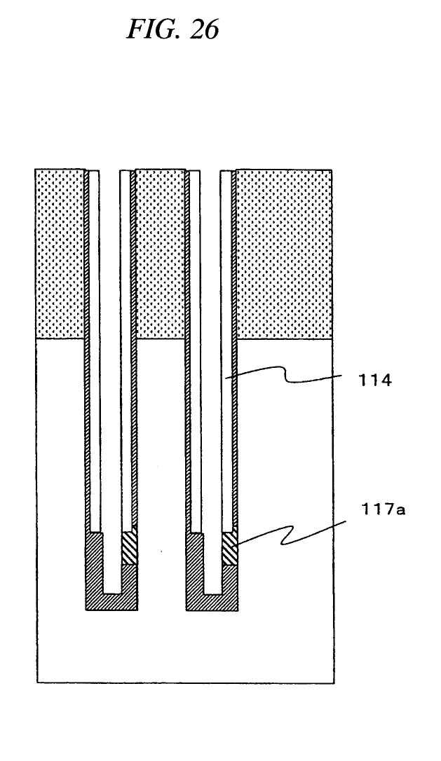

As shown in FIG. 26, the arsenic-doped silicon films 117 and 111b are etched back by anisotropic dry etching. Thereby, in the lateral opening 100a, the sidewall protection insulation film 114 becomes a mask and the arsenic-doped silicon film 117 remains. A contact 117a is then formed in the semiconductor substrate 100.

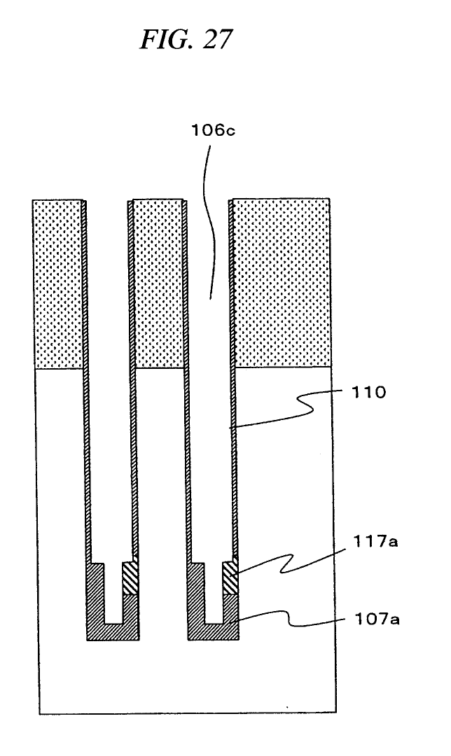

As shown in FIG. 27, the sidewall protection insulation film 114 made of a silicon nitride film is selectively removed, and the silicon oxide film 110 corresponding to the second insulation film is exposed. Thereby, the portion of the lateral opening 100a of the trench 106a formed in FIG. 10 can be converted from the silicon oxide film 107a to the contact 117a made of the arsenic-doped silicon film 117. In addition, a new trench 106c is formed in this step.

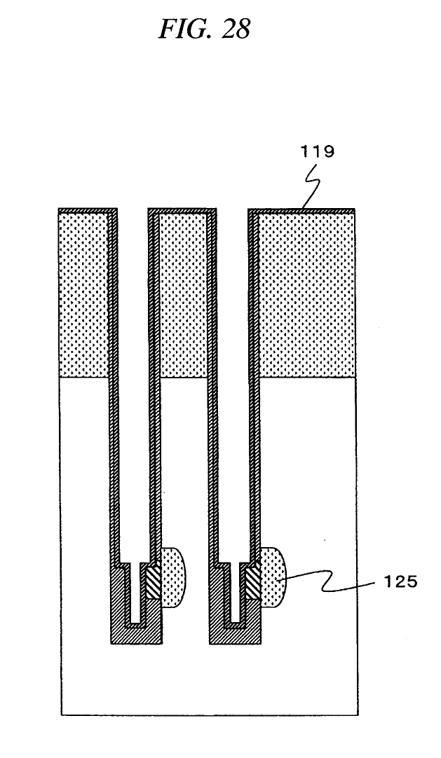

As shown in FIG. 28, a titanium nitride 119 having a thickness of 4 nm is formed in the whole surface including the inside of the trench 106c by the CVD method. The titanium nitride can be formed at a temperature of 650° C. using titanium tetrachloride and ammonia as a raw material gas. Meanwhile, prior to formation of the titanium nitride 119, titanium tetrachloride is plasma-processed in the same reaction chamber and then titanium having a thickness of 1 nm is formed in the whole surface of the semiconductor substrate. In the surface of the contact 117a made of an arsenic-doped silicon film, titanium is deposited and simultaneously low-resistance titanium silicide is formed. Thereby, the contact resistance can be reduced. Titanium formed on an insulation film of another region is nitrided at the time of formation of titanium nitride, and is converted to titanium nitride. In addition, in heat treatment at the time of formation of this titanium nitride 119, arsenic is diffused from the contact 117a made of an arsenic-doped silicon film to the silicon substrate 100 and a diffusion layer 125 is formed. The formation of the diffusion layer 125 may be continuously performed after the arsenic-doped silicon film 117 shown in FIG. 25 is buried.

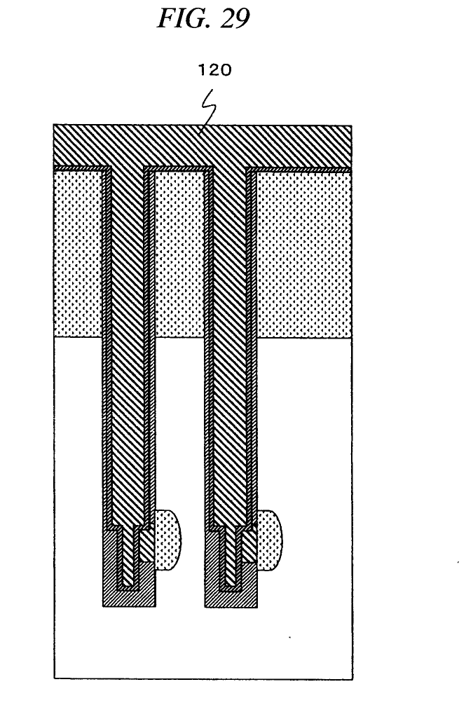

After the titanium nitride 119 is formed, as shown in FIG. 29, tungsten 120 is formed in the whole surface by the CVD method so as to bury the trench 106c.

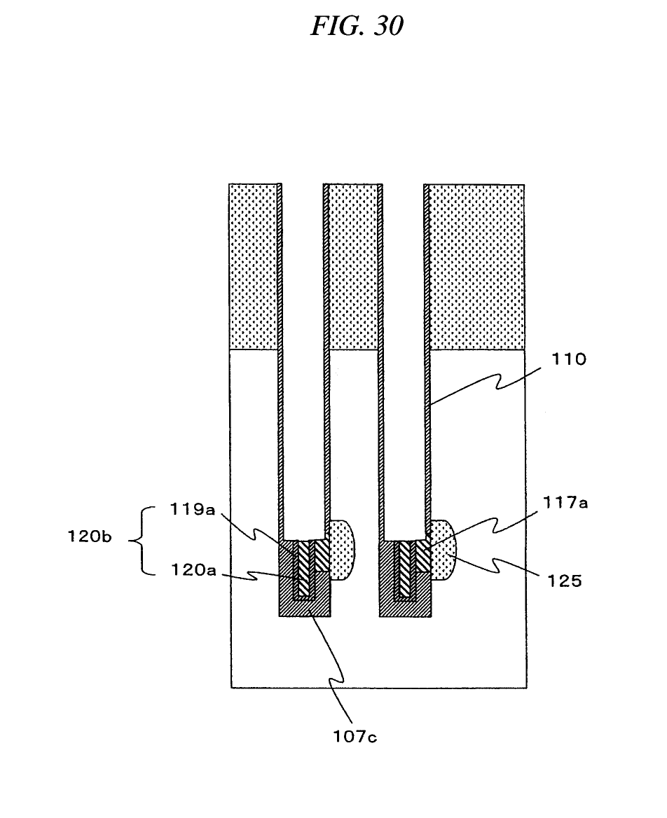

As shown in FIG. 30, the tungsten 120 and the titanium nitride 119 are etched back up to the position of the upper surface 107b of the silicon oxide film 107a by the anisotropic dry etching. Thereby, a bit line 120b composed of buried titanium nitride 119a and buried tungsten 120a is formed in the inside of the silicon oxide film 107a. The bit line 120b is connected to the diffusion layer 125 via titanium silicide (not shown) and the contact 117a.

After this, it is possible to complete the semiconductor device which is formed as a DRAM shown in FIG. 51 and FIG. 1 through a process of forming the word line, located above the bit line, in the X direction which is a direction perpendicular to the bit line extension direction, a process of forming a diffusion layer on the upper portion of the pillar by removing the mask silicon nitride film 104, a process of forming a capacitive contact plug, a process of forming a capacitor, a process of forming an interconnection layer and the like (however, in the semiconductor device of the embodiment, the configuration of the first insulation film is different from that of FIG. 51).

According to the embodiment, the trench 106 includes a first region in which the bit line 120b is formed in the bottom thereof, and a second region located above the bit line 120b. That is, the trench region located below the upper surface of the bit line 120b which is rectangular in shape when seen in a cross-sectional view is the first region, and the trench region located above the upper surface of the bit line 120b is the second region.

In addition, in the first region, the silicon oxide film 107c interposed between the bottom face of the bit line 120b and the bottom face of the trench 106 opposite to the bottom face of the bit line 120b is formed of the first insulation film. In the second region, the silicon oxide film 110 formed in the inner wall of the trench by the thermal oxidation method is formed of the second insulation film. In the embodiment, the silicon oxide film 107c formed of the first insulation film is formed so as to have a thickness of 10 nm, and thus it is possible to avoid a problem that the leakage current is generated due to a shortage of the dielectric strength voltage of the bit line 120b and the semiconductor substrate 100. In addition, it is possible to avoid the generation of the leakage current between the adjacent bit lines.

Further, in the embodiment, the opening width of the trench 106 which is initially formed is set to 45 nm. As mentioned above, when the first insulation film is formed with a thickness of 10 nm, the thickness of the second insulation film is set to 17 nm. In this step, the opening width of the remaining trench is set to 11 nm. Supposing that the processes of the embodiment are progressed to this state, the trench is nearly blocked in the step of forming the sidewall protection film 114 with a thickness of 5 nm which is made of a silicon nitride film in FIG. 13, and after that the process subsequent to the formation (FIG. 15) of the sidewall 115 (its thickness is 7 nm) made of titanium nitride cannot be carried out, and thus there occurs a problem that the bit line cannot be formed. However, in the embodiment, the silicon oxide film 107, having a thickness of 17 nm, formed in the second region is removed beforehand, and the thermal oxidation is newly carried out, and then the second insulation film made of the silicon oxide film 110 having a thickness of 3 nm is formed. Therefore, the space opening width of the trench remaining in each of the process termination steps can be secured, and the bit line can be formed by avoiding the problem that the trench is blocked during the forming process.

As mentioned above, according to the embodiment, it is possible to avoid the generation of the leakage current between the bottom face of the bit line and the semiconductor substrate in the step in which the semiconductor device is completed, and to form the bit line by avoiding a problem that a plurality of thin films cannot be formed due to a reduction in the trench space of the second region among the processes leading to the formation of the bit line.

### SECOND EMBODIMENT

In the first embodiment, there has been described the method in which the silicon oxide film initially formed in the inner surface of the trench is formed with a large thickness in order to secure the dielectric strength voltage between the bit line and the semiconductor substrate, and after that, the thick silicon oxide film formed in the second region of the trench is removed beforehand, and then the thin silicon oxide film is reformed by the thermal oxidation method.

In the second embodiment, after the trench is formed, the first insulation film having a large thickness and the second insulation film having a small thickness are simultaneously formed by one thermal oxidation. This method will be described with reference to FIGS. 31 to 33.

First, similarly to FIG. 5 of the first embodiment, the trench 106 is formed in the semiconductor substrate 100 using the silicon nitride film 104 as a mask.

As shown in FIG. 31, oxygen ions (O²⁺) are implanted into the whole surface from the direction perpendicular to the surface of the silicon substrate 100 by an ion implantation method set to the following conditions.

Dopant: O²⁺

Dose amount: 1×10¹⁶ atoms/cm² to 1×10¹⁸ atoms/cm²

Implantation energy: 3 KeV to 30 KeV

Thereby, an oxygen implantation region 121 existing at an oxygen concentration of 8×10¹⁹ atoms/cm³ to 8×10²⁰ atoms/cm³ is formed in the surface region of the semiconductor substrate (range having a depth of 10 nm from the bottom face of the trench 106 to the substrate side) corresponding to the bottom face of the trench 106.

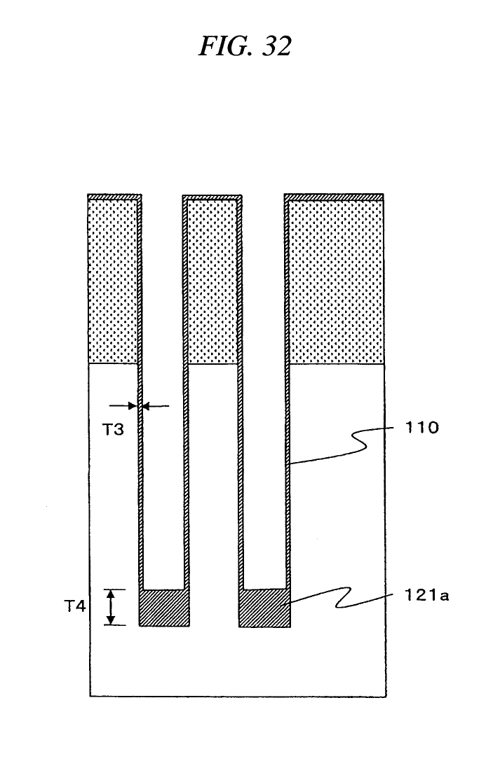

As shown in FIG. 32, the silicon oxide film 110 corresponding to the second insulation film is formed so as to have a thickness T3 of 4 nm in the lateral face of the trench 106 by the thermal oxidation method in which the heating temperature is set to 800° C. to 900° C. At this time, the oxidation reaction is promoted in the bottom face of the trench 106 by conversion of the previously implanted oxygen to oxidation species. As a result, in the bottom face of the trench 106, a silicon oxide film 121a corresponding to the first insulation film is formed with a thickness T4 of 8 nm. The lower limit of the thickness required for the first insulation film is 6 nm, and the silicon oxide film having a larger thickness than this lower limit thickness can be obtained.

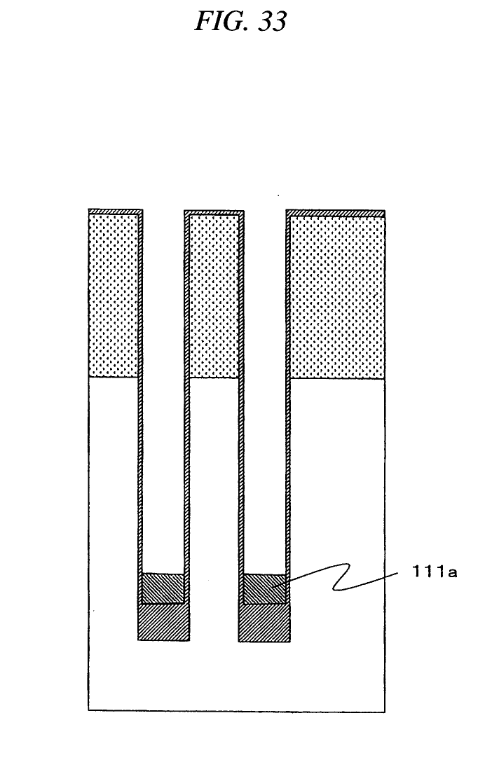

As shown in FIG. 33, the buried arsenic-doped silicon film 111a is formed on the silicon oxide film 121a corresponding to the first insulation film, and subsequently, the bit line is formed according to the same process as that of the first embodiment, so that the DRAM finally is obtained.

Although oxygen is used as the ionic species bringing about enhanced oxidation in the second embodiment, the ionic species may be impurities such as phosphorus, arsenic, and boron without being limited thereto. When these impurities are used, it is preferable that an atmosphere in which thermal oxidation is performed is a water vapor containing atmosphere, and that the temperature is within the range of 700° C. to 800° C. Thereby, it is possible to obtain the silicon oxide film having a thickness 1.8 to 2.5 times that of the case where the impurities are not implanted.

### THIRD EMBODIMENT

In the above-mentioned second embodiment, after the trench is formed, there has been described the method in which the first insulation film having a large thickness and the second insulation film having a small thickness are simultaneously formed by one thermal oxidation. The third embodiment relates to a method in which the first insulation film and the second insulation film are all formed with a small thickness, and then the first insulation film is formed with a large thickness. Hereinafter, the third embodiment will be described with reference to FIGS. 34 to 38.

First, similarly to FIG. 5 of the first embodiment, the trench 106 is formed in the semiconductor substrate 100 using the silicon nitride film 104 as a mask. As shown in FIG. 34, a silicon oxide film 110a having a thickness of 3 nm is formed in the inner surface of the trench 106 by the thermal oxidation method in which the heating temperature is set to 800° C. to 900° C.

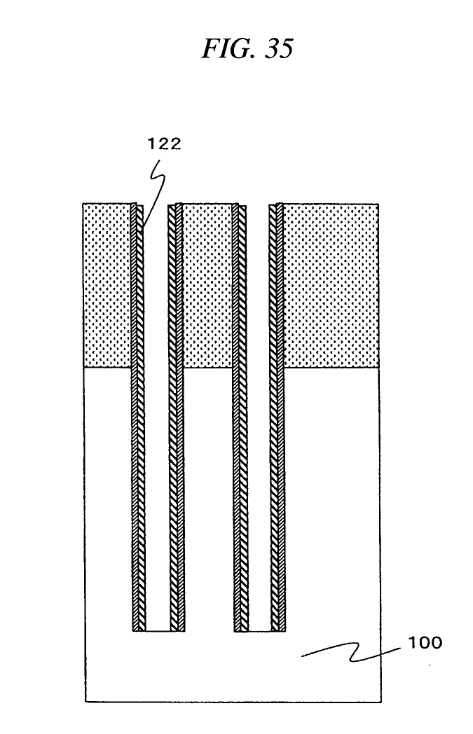

As shown in FIG. 35, after a silicon nitride film having a thickness of 7 nm is formed over the whole surface including the inside of the trench 106 by the decompression CVD method, the sidewall 122 is formed by etching back the silicon nitride film through the anisotropic dry etching.

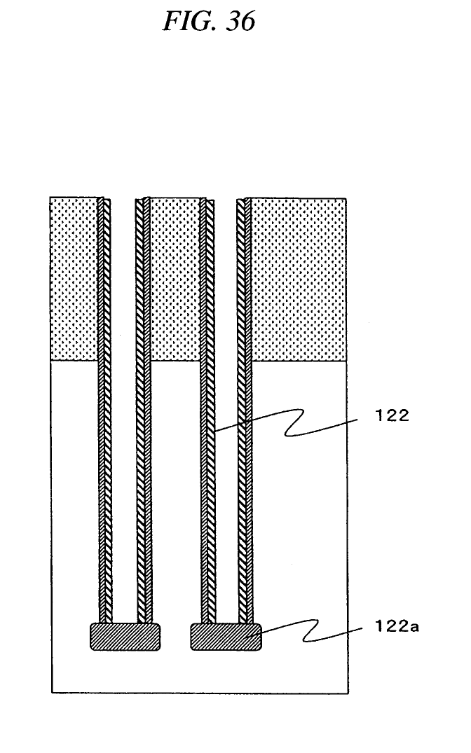

As shown in FIG. 36, the thermal oxidation in which the heating temperature is set to 800° C. to 900° C. is performed. At this time, since the silicon substrate 100 is covered with the sidewall 122 made of a silicon nitride film, oxidation in the lateral face of the trench 106 does not progress, and only the bottom face of the trench 106 can be selectively oxidized. As a result, a first insulation film 122a formed in the bottom face of the trench 106 is formed with a thickness of 20 nm to 30 nm. As seen from the above, only the first insulation film can be formed with a large thickness while maintaining the thickness of the silicon oxide film 110a corresponding to the second insulation film of the trench 106 at 3 nm.

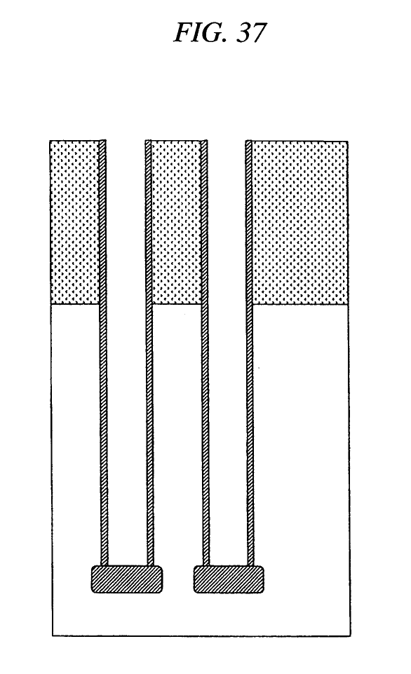

After this, as shown in FIG. 37, the sidewall 122 is removed using phosphoric acid heated at a temperature of 130° C. to 160° C.

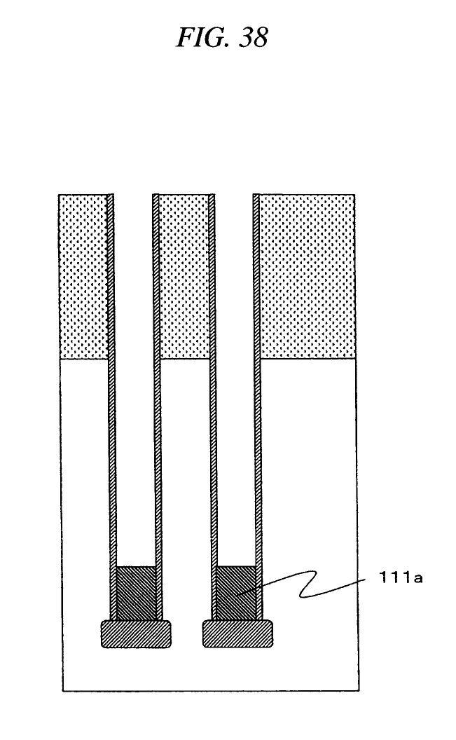

Subsequently, as shown in FIG. 38, the arsenic-doped silicon film 111a is formed on the first insulation film 122a formed in the bottom face of the trench 106. Hereinafter, similarly to the first embodiment, the DRAM is formed by continuing the processes.

### FOURTH EMBODIMENT

In the above-mentioned third embodiment, there has been described the method in which the first insulation film and the second insulation film are all formed with a small thickness using two thermal oxidation processes, and then the first insulation film is formed with a large thickness. The fourth embodiment relates to a method in which an insulation film formed by the CVD method is used in a portion of the first insulation film. Hereinafter, the fourth embodiment will be described with reference to FIGS. 39 to 41.

First, similarly to FIG. 34 of the third embodiment, the trench 106 is formed in the semiconductor substrate 100 using the silicon nitride film 104 as a mask. After this, the silicon oxide film 110a having a thickness of 3 nm is formed in the inner surface of the trench 106 by the thermal oxidation method in which the heating temperature is set to 800° C. to 900° C.

As shown in FIG. 39, a silicon oxide film 123 having a film thickness of 80 nm on a wide plane surface is formed by an HDP-CVD (High Density Plasma-CVD) method set to the following film formation conditions. The film thickness on a wide plane surface means a film thickness of a portion, formed on the silicon nitride film 104 on the extreme right, of which the upper surface is formed in a planar manner in FIG. 39. In the HDP-CVD, since an action of ion etching and an action of film deposition exist together, the inclined surface having an angle of about 45° is formed at the stepped portion, and deposition is stopped at the narrow area portion. Deposition continues at the planar surface which is not affected by the influence of the step difference at the wide area portion.

Process gas and flow rate: monosilane (SiH₄)/oxygen (O₂)/hydrogen (H₂)=130/300/300 sccm

Heating temperature: 200° C.

Pressure: 40 mTorr

High-frequency power: 6000 W

Since the HDP-CVD method has high directivity of film formation due to an ion effect, a CVD insulation film 123a having a thickness of 80 nm is formed on the silicon oxide film 110a formed in the bottom face of the trench 106. The CVD insulation film is not substantially formed in the lateral face of the inner wall of the trench 106.

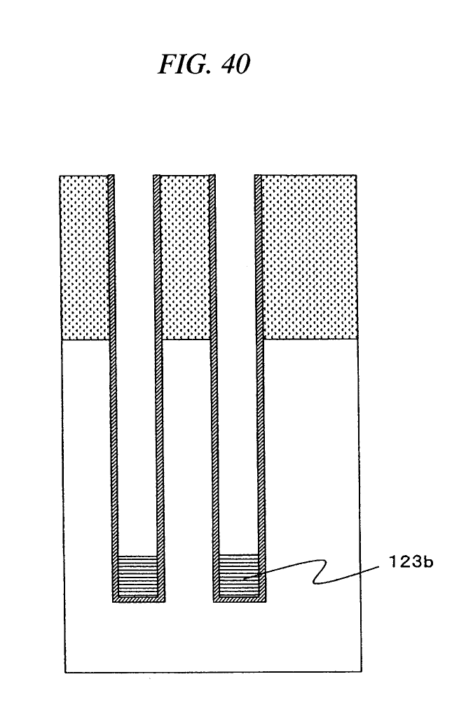

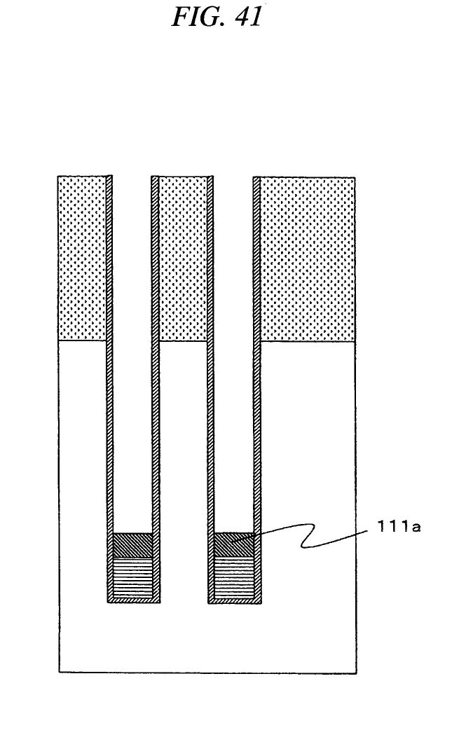

As shown in FIG. 40, a CVD insulation film 123b having a thickness of 40 nm is left behind on the bottom face of the trench 106 by etching back the CVD insulation film 123 and 123a through the anisotropic dry etching. Thereby, the silicon oxide film 110a having a thickness of 2 nm and the CVD insulation film 123b having a thickness of 40 nm make up a laminated structure on the bottom face of the trench 106, and form the first insulation film. In addition, the first insulation film has a larger thickness than that of the silicon oxide film 110a on the lateral face of the trench 106 which is the second insulation film. Subsequently, as shown in FIG. 41, the buried arsenic-doped silicon film 111a is formed on the first insulation film formed in the bottom face of the trench 106, and after this, the bit line is formed according to the same process as that of the first embodiment, so that the DRAM is finally obtained.

### FIFTH EMBODIMENT

The above-mentioned first embodiment uses the method of burying the silicon film 109 within the trench in which the silicon oxide film 107 is formed. The fifth embodiment relates to a method of burying an insulating material such as silicate glass within the trench in which the silicon oxide film 107 is formed. Hereinafter, the fifth embodiment will be described with reference to FIGS. 42 to 45.

First, similarly to FIG. 6 of the first embodiment, the silicon oxide film 107 is formed so as to have a thickness T1 of 10 nm in the bottom face of the trench 106 by the thermal oxidation method.

As shown in FIG. 42, the trench 106 is completely filled with an insulation film 124 which is silicate glass and the like by the decompression CVD method set to the following film formation conditions.

Process gas and flow rate: TEOS [Tetra Ethyl Ortho Silicate] (Si(OC₂H₅)₄)/oxygen (O₂)/helium (He)/argon (Ar)=250/2300/700/300 sccm

Heating temperature: 360° C.

Pressure: 400 Pa

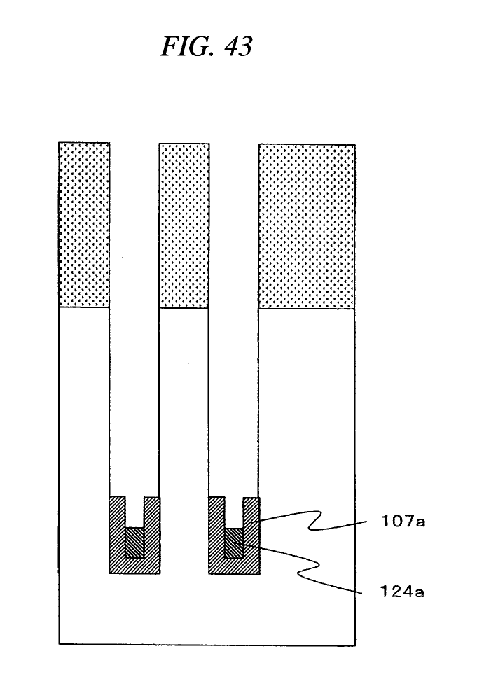

As shown in FIG. 43, the insulation film 124 is removed up to a thickness of 40 nm by controlling the treating time of an etch-back method. At this time, although the insulation film 107 formed in the lateral portion of the trench 106 is also removed, the etching rate is reduced by 88% or so with respect to the insulation film 124, and thus its height becomes 100 nm or so. Thereby, the first insulation film having a thickness of 50 nm can be formed in which the insulation film 124a having a thickness of 40 nm and the silicon oxide film 107a having a thickness of 10 nm are laminated and remain in the bottom portion of the trench 106.

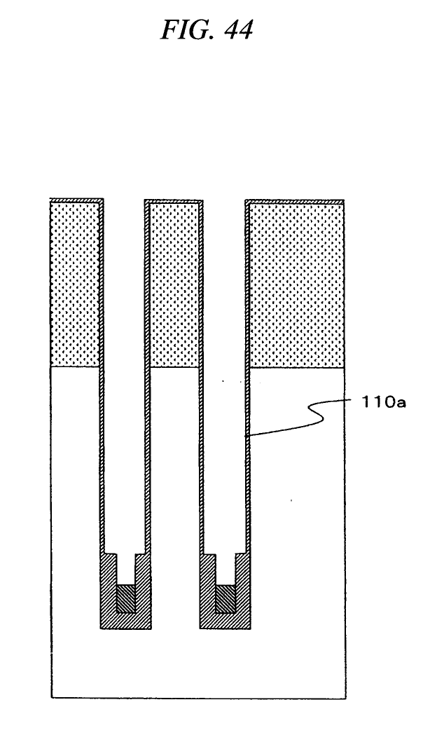

As shown in FIG. 44, the silicon oxide film 110a having a thickness of 3 nm corresponding to the second insulation film is formed in the lateral face corresponding to the second region of the trench 106 by the thermal oxidation method in which the heating temperature is set to 800° C. to 900° C.

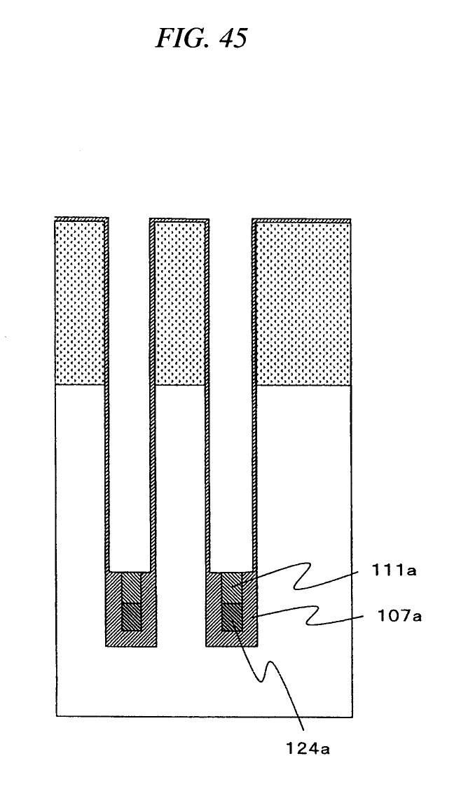

Subsequently, as shown in FIG. 45, the buried arsenic-doped silicon film 111a is formed on the first insulation film formed in the bottom face of the trench 106. Hereinafter, the bit line is formed according to the same process as that of the first embodiment, so that the DRAM is finally obtained.

### SIXTH EMBODIMENT

The sixth embodiment relates to a method in which the second embodiment and the fifth embodiment are combined. Hereinafter, the sixth embodiment will be described with reference to FIGS. 46 to 50.

First, similarly to FIG. 5 of the first embodiment, the trench 106 is formed in the semiconductor substrate 100. Similarly to FIG. 31 of the second embodiment, oxygen ions (O²⁺) are implanted into the whole surface from the direction perpendicular to the surface of the silicon substrate 100 by the ion implantation method. Thereby, the oxygen implantation region 121 existing at an oxygen concentration of 8×10¹⁹ atoms/cm³ to 8×10²⁰ atoms/cm³ is formed within the semiconductor substrate corresponding to the bottom face of the trench 106.

As shown in FIG. 46, the silicon oxide film 110 having a thickness of 4 nm is formed in the lateral face of the trench 106, and the silicon oxide film 121a having a thickness of 8 nm is formed in the bottom face of the trench 106, by performing the thermal oxidation method in which the heating temperature is set to 800° C. to 900° C.

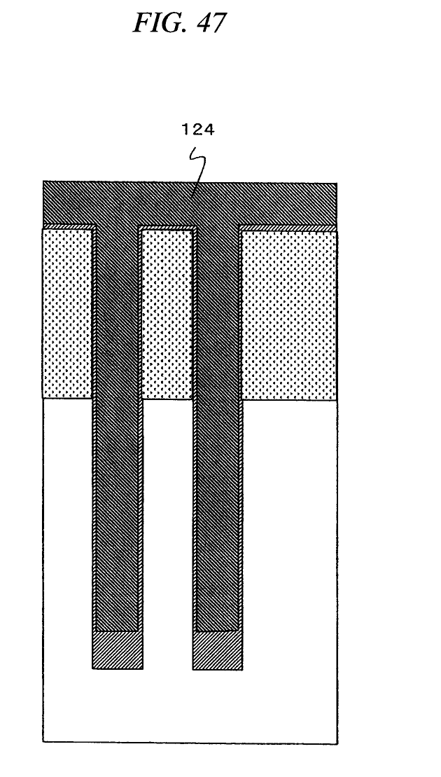

As shown in FIG. 47, the trench 106 is completely filled with the insulation film 124 which is silicate glass and the like by the decompression CVD method.

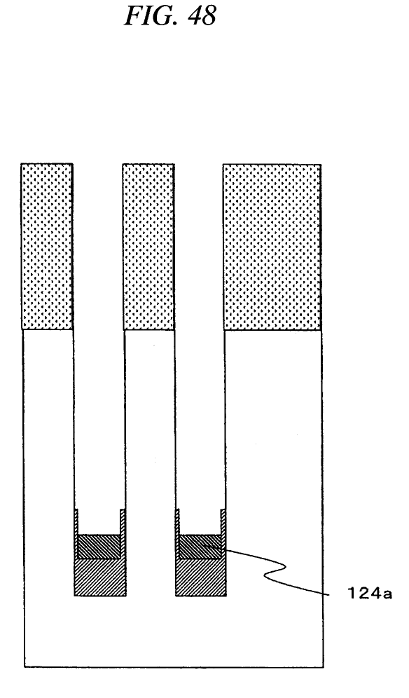

As shown in FIG. 48, a portion of the insulation film 124 is removed by controlling the treating time of the etch-back method, and the insulation film 124a having a thickness of 40 nm is left behind. At this time, although the insulation film 110 formed in the lateral portion of the trench 106 is also removed, the etching rate is reduced more than that of the insulation film 124, and thus the insulation film 110 is higher than the insulation film 124.

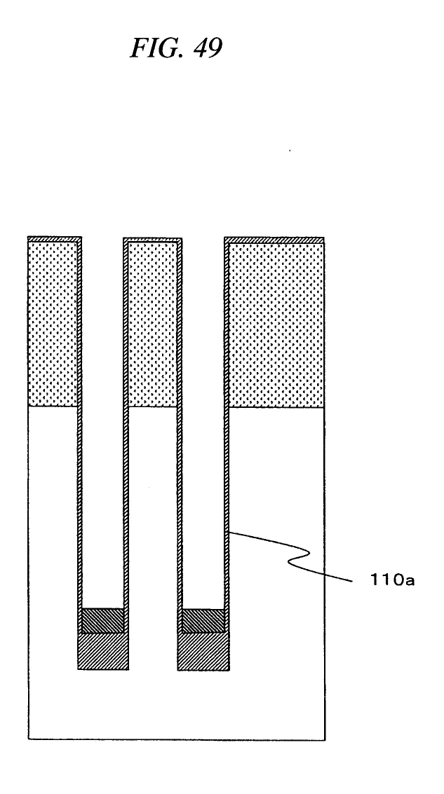

After this, as shown in FIG. 49, the silicon oxide film 110a having a thickness of 3 nm corresponding to the second insulation film is formed in the lateral face corresponding to the second region of the trench 106 by the thermal oxidation method in which the heating temperature is set to 800° C. to 900° C. Thereby, the first insulation film having a thickness of 48 nm can be formed in which the insulation film 124a having a thickness of 40 nm and the silicon oxide film 121 a having a thickness of 8 nm are laminated and remain in the bottom portion of the trench 106.

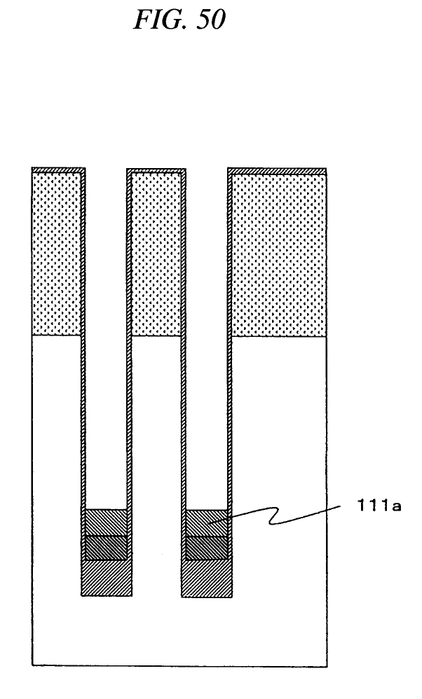

Subsequently, as shown in FIG. 50, the buried arsenic-doped silicon film 111a is formed on the first insulation film formed in the bottom face of the trench 106. Hereinafter, the bit line is formed according to the same process as that of the first embodiment, so that the DRAM is finally obtained.

Even in any of the above-mentioned first to sixth embodiments, the first insulation film just below the bottom face of the bit line is thickened. For this reason, it is possible to reduce the leakage current on the basis of the bit line. Further, since thickness is performed without greatly increasing an aspect ratio of the trench, a processing operation in the subsequent process can be easily carried out.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method of forming a semiconductor device, the method comprising:
forming a groove in a semiconductor substrate;
forming a first insulating film on a bottom surface of the groove and a second insulating film on a side surface of the groove, the second insulating film being thinner than the first insulating film; and
forming a conductive layer on the first insulating film.

2. The method according to claim 1, wherein forming the second insulating film on the side surface of the groove comprises thermally oxidizing the side surface of the groove.

3. The method according to claim 1, wherein forming the groove in the semiconductor substrate comprises forming a trench groove in the semiconductor substrate, and
forming the conductive layer comprises forming a bit line on the first insulating film.

4. The method according to claim 1, wherein forming the groove in the semiconductor substrate comprises forming the groove in a silicon substrate.

5. The method according to claim 4, wherein forming the first insulating film and the second insulating film comprises:
thermally oxidizing the bottom surface of the groove and the side surface of the groove to form a silicon oxide film on the bottom surface of the groove and the side surface of the groove;
forming a silicon film that fills the groove;
selectively removing the silicon oxide film and the silicon film to have the silicon oxide film and the silicon film reside on the bottom surface of the groove;
removing the silicon film to form the first insulating film on the bottom surface of the groove; and
thermally oxidizing the side surface of the groove to form the second insulating film on the side surface of the groove.

6. The method according to claim 4, wherein forming the first insulating film and the second insulating film comprises:
introducing oxygen into the silicon substrate through the groove to form an oxygen-introduced region under the bottom surface of the groove; and
thermally oxidizing the bottom surface of the groove and the side surface of the groove to form the first insulating film on the bottom surface of the groove and the second insulating film on the side surface of the groove.

7. The method according to claim 4, wherein forming the first insulating film and the second insulating film comprises:
thermally oxidizing the bottom surface of the groove and the side surface of the groove to form a silicon oxide film on the bottom surface of the groove and the second insulating film on the side surface of the groove;
forming a silicon nitride film which covers the silicon oxide film on the bottom surface of the groove; and
thermally oxidizing the silicon oxide film on the bottom surface of the groove while the silicon nitride film covering the side surface of the groove to increase a thickness of the silicon oxide film to form the first insulating film on the bottom surface of the groove.

8. The method according to claim 7, wherein forming the first insulating film and the second insulating film further comprises:
removing the silicon nitride film.

9. The method according to claim 4, wherein forming the first insulating film and the second insulating film comprises:
thermally oxidizing the bottom surface of the groove and the side surface of the groove to form a silicon oxide film on the bottom surface of the groove and the second insulating film on the side surface of the groove;
performing a high density plasma chemical vapor deposition to form an additional silicon oxide film on the silicon oxide film on the bottom surface of the groove; and
selectively removing the additional silicon oxide film to form the first insulating film on a bottom surface of the groove, the first insulating film comprising the silicon oxide film and the additional silicon oxide film.

10. The method according to claim 4, wherein forming the first insulating film and the second insulating film comprises:
thermally oxidizing the bottom surface of the groove and the side surface of the groove to form a silicon oxide film on the bottom surface of the groove and the side surface of the groove;
forming a silicate glass that fills the groove;
selectively removing the silicon oxide film and the silicate glass to form the first insulating film on the bottom surface of the groove, the first insulating film comprising the silicon oxide film and the silicate glass; and
thermally oxidizing the side surface of the groove to form the second insulating film on the side surface of the groove.

11. The method according to claim 4, wherein forming the first insulating film and the second insulating film comprises:
introducing oxygen into the silicon substrate through the groove to form an oxygen-introduced region under the bottom surface of the groove; and
thermally oxidizing the bottom surface of the groove and the side surface of the groove to form a silicon oxide film on the bottom surface of the groove and the second insulating film on the side surface of the groove;
forming a silicate glass that fills the groove;
selectively removing the silicon oxide film and the silicate glass to form the first insulating film on the bottom surface of the groove, the first insulating film comprising the silicon oxide film and the silicate glass; and
thermally oxidizing the side surface of the groove to form the second insulating film on the side surface of the groove.

12. The method according to claim 1, further comprising:
forming a contact layer on a selected region of the side surface of the groove; and
forming a diffusion layer in the semiconductor substrate, the diffusion layer being adjacent to the selected region of the side surface of the groove, the diffusion layer contacting the contact layer;
wherein forming the conductive layer comprises forming the conductive layer which contacts the first insulating film and the contact layer.

13. The method according to claim 12, wherein forming the contact layer on the selected region of the side surface of the groove comprises:
forming a side wall protection film which covers the second insulating film on the side surface of the groove, the side wall protection film being over the first insulating film on the bottom surface of the groove;
selectively removing the first insulating film and the second insulating film below the side wall protection film to expose the selected region of the side surface of the groove; and
forming the contact layer on the selected region of the side surface of the groove, the contact layer being under the side wall protection film and the second insulating film and over the first insulating film.

14. The method according to claim 13, wherein forming the diffusion layer comprises:
thermally diffusing an impurity from the contact layer into the semiconductor substrate through the selected region of the side surface of the groove.

15. The method according to claim 1, wherein forming the first insulating film comprises forming the first insulating film having a thickness in the range of 6 nm to 60 nm.

16. The method according to claim 1, wherein forming the second insulating film comprises forming the second insulating film having a thickness in the range of 1 nm to 5 nm.

17. A method of forming a semiconductor device, the method comprising:
forming a groove in a silicon substrate;
forming a first insulating film on a bottom surface of the groove and a second insulating film on a side surface of the groove, at least the second insulating film being formed by thermal oxidation, the second insulating film being thinner than the first insulating film;
selectively removing the first insulating film and the second insulating film to expose a selected region of the side surface of the groove;
forming a contact layer on the selected region of the side surface of the groove;
thermally diffusing an impurity from the contact layer into the semiconductor substrate through the selected region of the side surface of the groove to form a diffusion layer in the semiconductor substrate, the diffusion layer being adjacent to the selected region of the side surface of the groove, the diffusion layer contacting the contact layer; and
forming a conductive layer on the first insulating film.

18. The method according to claim 17, wherein forming the first insulating film comprises:
thermally oxidizing the bottom surface of the groove.

19. The method according to claim 17, wherein forming the first insulating film comprises:
performing a high density plasma chemical vapor deposition.

20. A method of forming a semiconductor device, the method comprising:
forming a trench groove in a silicon substrate;
thermally oxidizing a bottom surface of the groove to form a first insulating film on the bottom surface of the groove;
thermally oxidizing a side surface of the groove to form the second insulating film on the side surface of the groove, the second insulating film being thinner than the first insulating film; and
forming a bit line on the first insulating film.
